(19) United States
(12) Patent Application Publication
(10) Pub. No.: US 2024/0087845 A1
(43) Pub. Date: Mar. 14, 2024

(54) ELECTRON BEAM WRITING APPARATUS AND ELECTRON BEAM WRITING METHOD

(71) Applicant: NuFlare Technology, Inc., Yokohama-shi (JP)

(72) Inventors: Haruyuki NOMURA, Yokohama-shi (JP); Hirofumi MORITA, Setagaya-ku (JP)

(73) Assignee: NuFlare Technology, Inc., Yokohama-shi (JP)

(21) Appl. No.: 18/355,681

(22) Filed: Jul. 20, 2023

Related U.S. Application Data
(63) Continuation of application No. PCT/JP2022/034317, filed on Sep. 14, 2022.

(51) Int. Cl. H01J 37/317; G03F 7/20; H01J 37/302

(52) U.S. Cl. CPC H01J 37/3175; G03F 7/2061; H01J 37/3026; H01J 2237/31776

(57) ABSTRACT

An electron beam writing apparatus according to the present invention includes a potential regulating member arranged to be upstream of a target object in the case where the target object is placed on a stage, and configured to be set to have a fixed potential being positive with respect to the target object, a potential applying circuit configured to apply a voltage to the target object or the potential regulating member so that the potential regulating member has the fixed potential, and a correction circuit configured to correct a positional deviation of the electron beam on a surface of the target object which occurs in the case where the target object is irradiated with the electron beam in the state in which the potential regulating member has the fixed potential.

### CROSS-REFERENCE TO RELATED APPLICATION

This application is a continuation application based upon and claims the benefit of priority from prior International Application PCT/JP2022/034317, the International Filing Date of which is Sep. 14, 2022. The contents described in PCT/JP2022/034317 are incorporated herein by reference.

### BACKGROUND OF THE INVENTION

### Field of the Invention

The present invention relates to an electron beam writing apparatus and electron beam writing method. For example, it relates to a method for correcting a positional deviation occurring in multiple beam writing.

### RELATED ART

The lithography technique which advances miniaturization of semiconductor devices is extremely important as a unique process whereby patterns are formed in semiconductor manufacturing. In recent years, with high integration of LSI, the circuit line width required for semiconductor devices is becoming increasingly narrower year by year. The electron beam writing technique, which intrinsically has excellent resolution, is used for writing on a wafer and the like with electron beams.

As an example, there is a writing apparatus using multiple beams. Since it is possible for multiple beam writing to apply multiple beams at a time, the writing throughput can be greatly increased in comparison with single electron beam writing. For example, a writing apparatus employing the multiple beam system forms multiple beams by letting an electron beam emitted from an electron gun pass through a mask having a plurality of holes, performs blanking control for each beam, reduces each unblocked beam by an optical system, and deflects it by a deflector to irradiate a desired position on a target object.

In electron beam writing, a reflected electron and a secondary electron are emitted from a target object when being irradiated with electron beams. If such secondary electrons, and the like return to the target object, its surface becomes charged, which causes a problem that the irradiation position of the electron beam deviates.

There is disclosed a method in which, in order not to return the secondary electron, etc. emitted from the target object surface thereto, an electrostatic lens composed of an annular three-stage electrode is used such that a positive electric potential is variably applied to the second stage electrode, and a positive fixed potential higher than the variable potential applied to the second electrode is applied to the first stage electrode (e.g., refer to JP-A-2018-170435). During writing, however, on the target object surface or in its vicinity, the electrostatic lens changes the positive potential to be applied to the second electrode by about several 10V to several 100V. In connection with this, during the writing, the potential distribution at the target object surface is changed, resulting in hindering to correct the positional deviation.

Further, there is proposed a writing apparatus employing a charge effect correction method which, when a target object becomes charged, calculates an amount of correction for a beam irradiation position by obtaining a charge amount distribution with respect to a positional deviation due to the charging phenomenon, and applies a beam to the position corrected based on the correction amount (e.g., refer to JP-A-2009-260250 and JP-A-2011-040450).

### BRIEF SUMMARY OF THE INVENTION

According to one aspect of the present invention, an electron beam writing apparatus includes
an emission source configured to emit an electron beam;
a stage configured to mount thereon a target object on which a pattern is to be written with the electron beam;
a potential regulating member arranged to be upstream of the target object in a case where the target object is placed on the stage, and configured to be set to have a fixed potential being positive with respect to the target object;
a potential applying circuit configured to apply a voltage to one of the target object and the potential regulating member so that the potential regulating member has the fixed potential; and
a correction circuit configured to correct a positional deviation of the electron beam on a surface of the target object which occurs in a case where the target object is irradiated with the electron beam in a state in which the potential regulating member has the fixed potential.

According to another aspect of the present invention, an electron beam writing method includes
applying a constant voltage to one of a target object, which is placed on a stage, and a potential regulating member, which is arranged at an upstream of the target object, so that the potential regulating member has a fixed potential being positive with respect to the target object;
correcting a positional deviation of an electron beam on a surface of the target object which occurs in a case where the target object is irradiated with the electron beam in a state in which the potential regulating member has the fixed potential; and
writing a pattern on the target object with the electron beam.

### BRIEF DESCRIPTION OF DRAWINGS

FIG. 1 is a conceptual diagram showing an example of the main configuration of a writing apparatus according to a first embodiment.

FIG. 2 is a conceptual diagram for explaining operations of a variable-shaped type writing apparatus according to the first embodiment.

FIG. 3 is a top view showing an example of the configuration of a substrate cover according to the first embodiment.

FIG. 4 is a diagram for explaining an example of an electric field formed between an electrode substrate and a target object according to the first embodiment.

FIG. 5 is a diagram for explaining another example of the electric field between the electrode substrate and the target object according to the first embodiment.

FIG. 6 is a flowchart showing main steps of a writing method according to the first embodiment.

FIG. 7 is a diagram showing an example of an evaluation pattern according to the first embodiment.

FIG. 8 is a diagram showing an example of a positional deviation map according to the first embodiment.

FIG. 9 is a diagram showing a part of the configuration of a writing apparatus according to a modified example of the first embodiment.

FIG. 10 is a diagram showing an example of a potential regulating member according to a modified example of the first embodiment.

FIG. 11 is a top view showing another example of the potential regulating member according to a modified example of the first embodiment.

FIG. 12 is a sectional view showing another example of the potential regulating member and a target object according to a modified example of the first embodiment.

FIG. 13 is a top sectional view showing another example of the potential regulating member according to a modified example of the first embodiment.

FIG. 14 is a front sectional view showing another example of the potential regulating member and a target object according to a modified example of the first embodiment.

FIG. 15 is a sectional view showing another example of the potential regulating member and a target object according to a modified example of the first embodiment.

FIG. 16 is a sectional view showing another example of the potential regulating member and a target object according to a modified example of the first embodiment.

FIG. 17 is a diagram for explaining an example of an electric field between an electrode substrate and a target object according to a modified example of the first embodiment.

FIG. 18 is a block diagram showing an example of the configuration of a writing apparatus according to a second embodiment.

FIG. 19 is a flowchart showing an example of main steps of a writing method according to the second embodiment.

FIG. 20 is a diagram showing an example of a mark according to the second embodiment.

FIG. 21 is a diagram showing an example of deflection sensitivity according to the second embodiment.

FIG. 22 is a block diagram showing an example of the configuration of a writing apparatus according to a third embodiment.

FIG. 23 is a flowchart showing a part of an example of main steps of a writing method according to the third embodiment.

FIG. 24 is a flowchart showing a part of an example of main steps of a writing method according to the third embodiment.

FIG. 25 is a diagram showing an example of an evaluation pattern according to the third embodiment.

FIG. 26 is a diagram showing an example of a positional deviation distribution according to the third embodiment.

FIG. 27 is a conceptual diagram showing the configuration of a writing apparatus according to a fourth embodiment.

FIG. 28 is a diagram showing an example of an irradiation region and a writing target pixel of multiple beams according to the fourth embodiment.

FIG. 29 is a flowchart showing the rest of an example of main steps of a writing method according to the fourth embodiment.

FIG. 30 is an illustration showing an example of a method for correcting a positional deviation according to the fourth embodiment.

FIG. 31 is an illustration showing an example of a method for correcting a positional deviation according to the fourth embodiment.

FIG. 32 is a block diagram showing an example of the configuration of a writing apparatus according to a fifth embodiment.

FIG. 33 is a flowchart showing an example of main steps of a writing method according to the fifth embodiment.

FIG. 34 is an illustration showing an example of an array shape according to the fifth embodiment.

### DETAILED DESCRIPTION OF THE INVENTION

The embodiments below provide an apparatus and method that can, in electron beam writing, correct a positional deviation highly precisely while preventing emitted secondary electrons, etc. from returning to the target object.

### First Embodiment

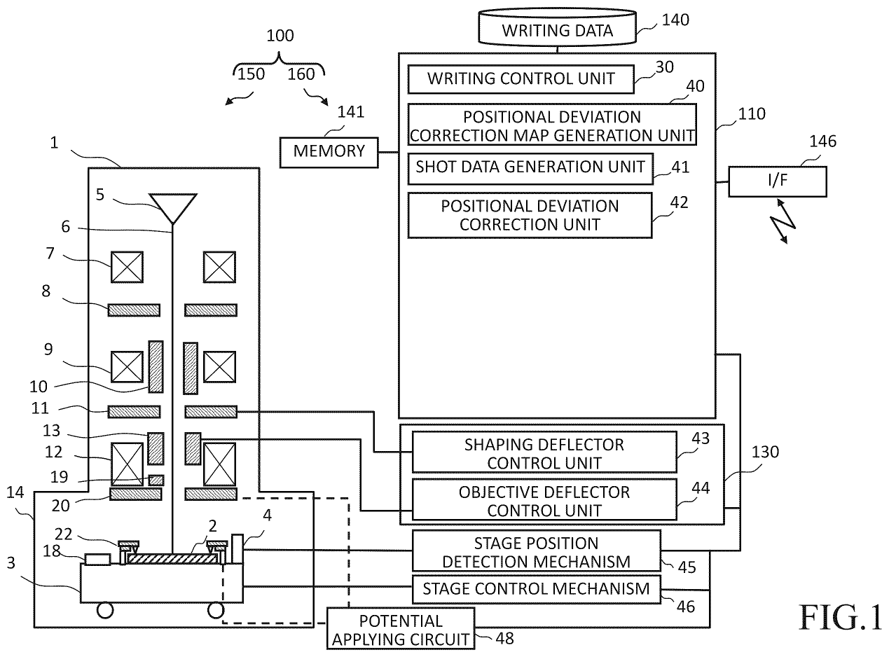

FIG. 1 is a conceptual diagram showing an example of the main configuration of a writing apparatus according to a first embodiment. In FIG. 1, a writing apparatus 100 includes a writing mechanism 150 and a control system circuit 160. The writing apparatus 100 is an example of an electron beam writing apparatus. The case of FIG. 1 shows, as the writing apparatus 100, a variable-shaped type writing apparatus using a single beam. The writing mechanism 150 includes an electron optical column 1 and a writing chamber 14. In the electron optical column 1, there are disposed an electron gun 5, an illumination lens 7, a first shaping aperture substrate 8, a projection lens 9, a deflector 10, a second shaping aperture substrate 11, an objective lens 12, a deflector 13, an electrode substrate 20 (an example of a potential regulating member), and a detector 19.

In the writing chamber 14, there is disposed an XY stage 3, on which a target object 2 to be written is placed. The target object 2 is, for example, a photomask used for exposure in semiconductor manufacturing and a semiconductor wafer for forming a semiconductor device. The photomask to be written may be a mask blank where nothing has been written. When being written, a resist film which is photosensitive to electron beams has been formed on the target object 2. On the XY stage 3, a mirror 4 for measuring the stage position is disposed at a position different from that where the target object 2 is placed. Further, on the XY stage 3, a mark 18 is disposed at a position different from that where the target object 2 is placed. The surface of the mark 18 is flush with that of the target object 2.

Furthermore, on the XY stage 3, there is disposed a substrate cover 22 which covers the outer peripheral part of the target object 2. The substrate cover 22 has a plurality of pins which pierce the outer peripheral part of the target object 2 from the above to penetrate through the resist film and to be electrically connected to the conductive light shielding film made of, for example, chromium, etc. arranged beneath the resist film.

The control system circuit 160 includes a control computer 110, a stage position detection mechanism 45, a stage control mechanism 46, a potential applying circuit 48, a deflection control circuit 130, a memory 141, a storage device 140 such as a magnetic disk device, and an external interface (I/F) circuit 146. The control computer 110, the stage position detection mechanism 45, the stage control mechanism 46, the potential applying circuit 48, the deflection control circuit 130, the memory 141, the storage device 140, and the external I/F circuit 146 are connected with each other by a bus (not shown). The deflection control circuit 130 is connected to the deflectors 10 and 13.

In the control computer 110, there are arranged a writing control unit 30, a positional deviation correction map generation unit 40, a shot data generation unit 41, and a positional deviation correction unit 42. Each of the “units” such as the writing control unit 30, the positional deviation correction map generation unit 40, the shot data generation unit 41, and the positional deviation correction unit 42 includes processing circuitry. The processing circuitry includes an electric circuit, a computer, a processor, a circuit board, a quantum circuit, a semiconductor device, or the like. Each of the “units” may use common processing circuitry (the same processing circuitry), or different processing circuitry (separate processing circuitry). Input data required in the writing control unit 30, the positional deviation correction map generation unit 40, the shot data generation unit 41, and the positional deviation correction unit 42, or calculated results are stored in the memory 141 each time.

In the deflection control circuit 130, there are provided functions, such as a shaping deflector control unit 43 and an objective deflector control unit 44. Each of the “units” such as the shaping deflector control unit 43 and the objective deflector control unit 44 includes processing circuitry. The processing circuitry includes an electric circuit, a computer, a processor, a circuit board, a quantum circuit, a semiconductor device, or the like. Each of the control units may use common processing circuitry (the same processing circuitry), or different processing circuitry (separate processing circuitry). Input data required in the shaping deflector control unit 43 and the objective deflector control unit 44, or calculated results are stored in a memory (not shown) each time.

The writing control unit 30 controls the whole of the writing apparatus 100. The deflector 10 is composed of, for example, four or more electrostatic electrodes, and controlled by the shaping deflector control unit 43. Each of the electrostatic electrodes is connected to a DAC amplifier (not shown). The deflection amount of the deflector 10 is controlled by controlling the potential applied to each DAC amplifier by the shaping deflector control unit 43.

The deflector 13 is composed of, for example, four or more electrostatic electrodes, and controlled by the objective deflector control unit 44. Each of the electrostatic electrodes is connected to a DAC amplifier (not shown). The deflection amount of the deflector 13 is controlled by controlling the potential applied to each DAC amplifier by the objective deflector control unit 44.

The XY stage 3 is driven by the stage control mechanism 46. The position of the XY stage 3 is detected by the stage position detection mechanism 45. The stage position detection mechanism 45 includes, for example, a laser length measuring device which applies a laser to the mirror 4 and measures the stage position using the principle of laser interferometry that measures the position based on interference between the incident light on the mirror 4 and the reflected light.

Writing data (layout data) defining a plurality of figure patterns to be written is input from the outside of the writing apparatus 100, and stored in the storage device 140.

In the example of FIG. 1, when the target object 2 is placed on the XY stage 3, the electrode substrate 20 is disposed at the upstream of the target object 2. An opening through which an electron beam passes is formed in the central part of the electrode substrate 20. The electrode substrate 20 has a surface oppositely facing the surface of the target object 2. Although, preferably, the lower surface of the electrode substrate 20 is parallel to the surface of the target object 2, it is not limited thereto. The lower surface of the electrode substrate 20 may be oblique to the surface of the target object 2. The lower surface of the electrode substrate 20 is formed to have a size covering a region of a predetermined range from the position irradiated with an electron beam on the surface of the target object 2 except for the opening in the central part. More preferably, the lower surface of the electrode substrate 20 is formed to have a size covering the surface of the target object 2.

Further, at least one of the electrode substrate and the substrate cover 22 is connected to the potential applying circuit 48.

Description other than configuration elements necessary for explaining the first embodiment is omitted in FIG. 1. It goes without saying that other configuration elements generally needed for the writing apparatus 100 are included therein.

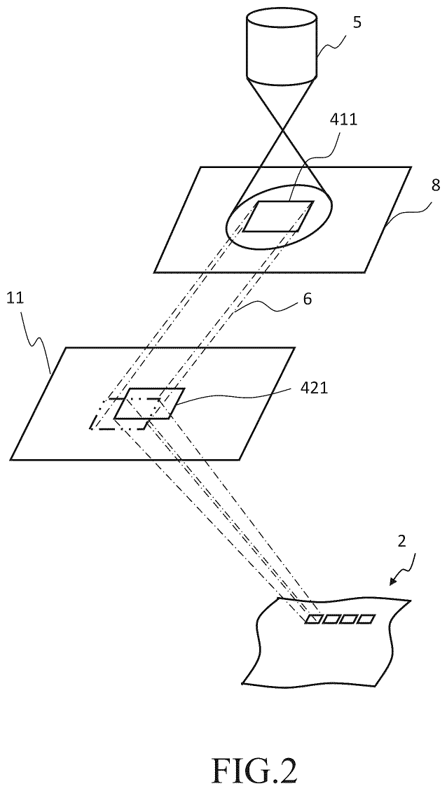

FIG. 2 is a conceptual diagram for explaining operations of a variable-shaped type writing apparatus according to the first embodiment. In FIG. 2, an electron beam 6 emitted from the electron gun 5 (emission source) illuminates the whole of the first shaping aperture substrate 8, in which a rectangular hole is formed, by the illumination lens 7. The electron beam 6 is controlled to be beam ON and beam OFF by a blanking mechanism (not shown). When in the state of beam OFF, the entire electron beam 6 is blocked by the first shaping aperture substrate 8. When in the state of beam ON, some parts of the electron beam 6 pass through a rectangular opening 411 in the first shaping aperture substrate 8. Thereby, the electron beam 6 is shaped to be rectangular. A beam for one shot is formed by an electron beam which passes through the opening 411 during a period from becoming beam ON to becoming beam OFF.

Then, the electron beam 6 of a first aperture image, which has passed through the rectangular opening 411 of the first shaping aperture substrate 8, is projected onto the second shaping aperture substrate 11 by the projection lens 9. The position of the first aperture image on the second shaping aperture substrate 11 is deflected by the deflector 10 controlled by the shaping deflector control unit 43, so as to variably change the beam shape and size of each shot. The objective lens 12 (an example of an electromagnetic lens) generates a magnetic field, and focuses the electron beam 6 having passed through the opening 421 on the surface of the target object 2. In other words, the electron beam 6 of a second aperture image, which has passed through the opening 421 of the second shaping aperture substrate 11, is focused by the objective lens 12 and deflected by the deflector 13 which is, for example, an electrostatic deflector, controlled by the objective deflector control unit 44, so as to be applied to a desired position on the target object 2 placed on the XY stage 3 movably arranged.

In performing writing processing, a plurality of stripe regions are set by dividing the writing region, where patterns are to be written, on the target object 2 into stripes by a predetermined width in the y direction, for example. Then, writing processing is carried out for each stripe region. While continuously moving the XY stage 3 in, for example, the −x direction, writing is relatively proceeded in the x direction. After completing writing one stripe region, the writing processing will be performed in the next stripe region adjacent in the y direction. By repeating the same processing, writing of all the stripe regions is completed.

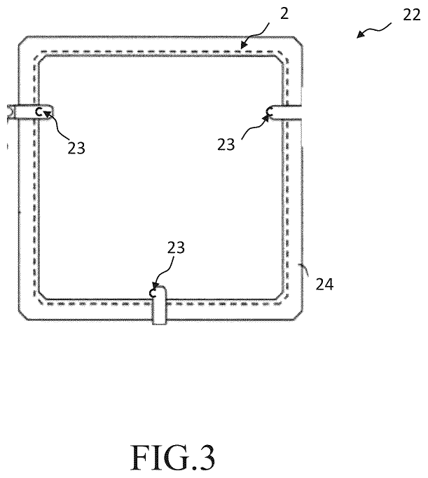

FIG. 3 is a top view showing an example of the configuration of a substrate cover according to the first embodiment. In FIG. 3, the dotted line shows the outer periphery of the target object 2. The substrate cover 22 includes an annular frame 24 and a plurality of pins 23. The frame 24 is formed to be the same shape as the target object 2. If the target object 2 is rectangular, the frame 24 is also formed to be rectangular. The inner peripheral size of the frame 24 is smaller than the circumferential size of the target object 2, and the circumferential size of the frame 24 is larger than that of the target object 2. The frame 24 is arranged such that it is overlapped with the outer peripheral part of the target object 2. In the case of FIG. 3, three pins 23 are arranged, for example. The three pins 23 are arranged at the positions whose phases are shifted from each other by, for example, about 120° with respect to the center position of the substrate cover 22. Each pin 23 is placed at the backside of the support plate which is arranged to protrude inside from the frame 24, and its sharpened point faces the target object. By arranging the substrate cover 22 on the surface of the target object 2, each pin 23 pierces the target object 2 from its surface side, and contacts with a conductive film arranged in the lower layer of the resist film, thereby becoming conductive with the target object 2. To each pin 23, wiring (not shown) is connected. This wiring is connected, for example, to the potential applying circuit 48 or to the ground. The ground connection may be performed inside the potential applying circuit 48 or outside of it.

According to the first embodiment, the electrode substrate 20 is set to have a positive fixed potential with respect to the target object 2, so that an unchanging electric field is produced between the electrode substrate and the target object 2. Thus, the potential applying circuit 48 applies a predetermined voltage to the target object 2 or the electrode substrate 20. Here, the fixed potential is not variably controlled, and the same applies to what is described below. For example, the voltage is applied as follows:

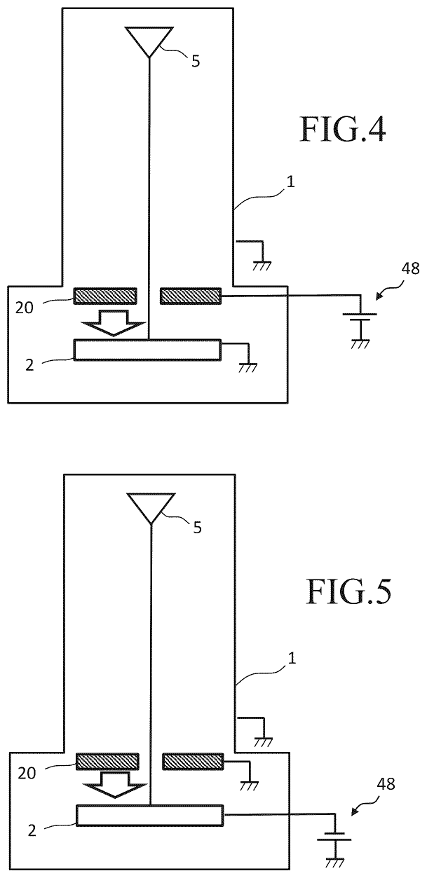

FIG. 4 is a diagram for explaining an example of an electric field formed between the electrode substrate 20 and the target object 2 according to the first embodiment. A positive constant voltage is applied from the potential applying circuit 48 so that the electrode substrate 20 may have a positive fixed potential with respect to the target object 2, and the target object 2 is connected to the ground through the pin 23 of the substrate cover 22 (not shown) in order to be a ground (GND) electric potential. Further, the electron optical column 1 is connected to the ground. Thereby, an unchanging electric field where the electrode substrate 20 has a positive potential with respect to the target object 2 is produced in the space between the electrode substrate 20 and the target object 2. Alternatively, it is also preferable to have the configuration described below.

FIG. 5 is a diagram for explaining another example of the electric field between the electrode substrate and the target object according to the first embodiment. In the case of FIG. 5, the electrode substrate 20 is connected to the ground and becomes a GND potential. Then, a negative voltage which has been set as a fixed value is applied from the potential applying circuit 48 to the target object 2 through the pin 23 of the substrate cover 22 (not shown), so that the target object 2 becomes a negative electric potential. Further, the electron optical column 1 is connected to the ground. Thereby, an unchanging electric field where the electrode substrate 20 has a positive potential with respect to the target object 2 is produced in the space between the electrode substrate and the target object 2.

As shown in FIGS. 4 and 5, a fixed electric field is produced between the electrode substrate 20 and the target object 2 without any member being disposed therebetween. For example, it is configured that an electrode to which an electric potential being variable during writing is applied is provided only at the upstream of the electrode substrate 20, and an electrostatic lens control electrode, etc. is not disposed between the electrode substrate 20 and the target object 2. Thereby, an unchanging electric field where the electrode substrate has a positive potential with respect to the target object 2 can be produced in the space between the electrode substrate 20 and the target object 2.

Therefore, when the surface of the target object 2 is irradiated with electron beams emitted from the electron gun 5, reflected electrons and/or secondary electrons which are emitted from the surface of the target object 2 are drawn to the electrode substrate 20 side which has a positive potential. Accordingly, secondary electrons, etc. do not return to the surface of the target object 2. On the surface of the target object 2, the pin 23 of the substrate cover 22 is arranged to protrude inside from the frame 24. If a structure is disposed between the electrode substrate 20 and the target object 2 in the state where an electric field has been produced, the potential of the surface of the target object 2 may not be constant, and therefore, a potential distribution may be generated on the surface of the target object 2. For example, due to a structure on the surface of the target object 2, which is overlapped with a portion, such as the pin 23, of the outer peripheral part of the target object 2, the potential of the surface of the target object 2 does not become fixed, thereby generating a potential distribution. However, according to the first embodiment, an unchanging electric field is produced between the electrode substrate 20 and the target object 2. Thus, the potential distribution on the surface of the target object 2 can be stabilized during writing processing.

In the state where the stabilized potential distribution exists on the surface of the target object 2, when the target object 2 is irradiated with an electron beam, a positional deviation occurs at the irradiation position of the electron beam. Then, the positional deviation attributed to the potential distribution formed on the surface of the target object 2 is to be corrected.

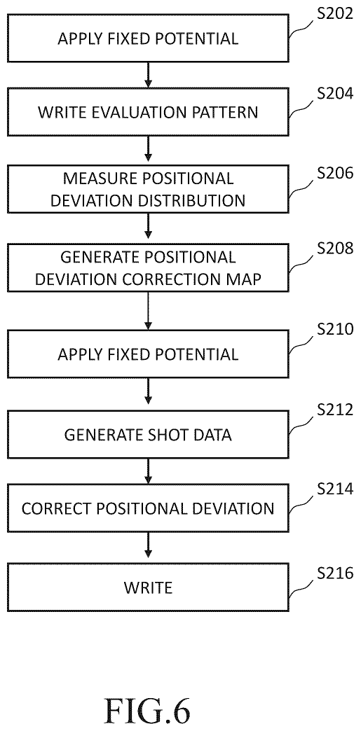

FIG. 6 is a flowchart showing main steps of a writing method according to the first embodiment. In FIG. 6, the writing method of the first embodiment executes a series of steps: a fixed potential applying step (S202), an evaluation pattern writing step (S204), a positional deviation distribution measuring step (S206), a positional deviation correction map generating step (S208), a shot data generating step (S210), a positional deviation correcting step (S212), a fixed potential applying step (S214), and a writing step (S216).

In the fixed potential applying step (S202), the potential applying circuit 48 applies a voltage to the target object 2 or the electrode substrate 20 so that the electrode substrate 20 may have a positive fixed potential with respect to the target object 2. Here, for example, in the state where the target object 2 is connected to the ground, a positive constant voltage is applied to the electrode substrate 20. Thereby, an unchanging electric field where the electrode substrate 20 has a positive electric potential with respect to the target object 2 is produced.

In the evaluation pattern writing step (S204), under the control of the writing control unit 30, the writing mechanism 150 writes an evaluation pattern on a resist-coated evaluation substrate (not shown) in the state of an electric field having been produced where the electrode substrate 20 has a positive electric potential with respect to the target object 2.

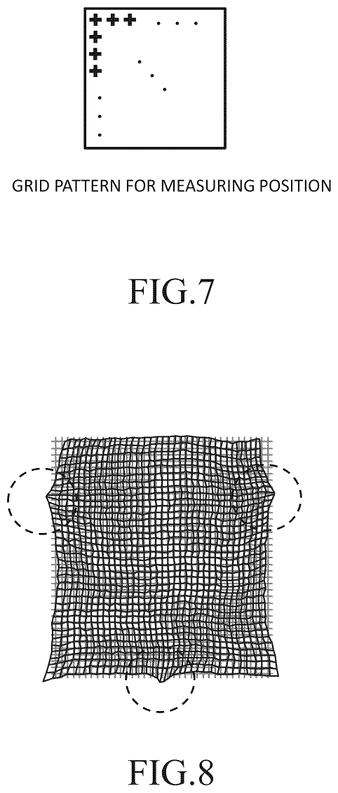

FIG. 7 is a diagram showing an example of an evaluation pattern according to the first embodiment. In FIG. 7, for example, a plurality of grid patterns arrayed at a predetermined pitch are used as evaluation patterns. Preferably, each grid pattern is a rectangular or cross pattern to easily measure a pattern position. In the case of FIG. 7, a cross pattern is shown as each grid pattern.

In the positional deviation distribution measuring step (S206), the evaluation substrate on which an evaluation pattern has been written is taken out from the writing apparatus 100, and asking is performed. Thereby, a resist pattern corresponding to the evaluation pattern can be obtained. Then, the position of each grid pattern of the evaluation pattern (resist pattern) is measured by a position measuring device (not shown). Measured position data is input to the writing apparatus 100 from the outside and stored in the storage device 140.

FIG. 8 is a diagram showing an example of a positional deviation map according to the first embodiment. In the case of FIG. 8, the positional deviation amount deviated from the position of each design grid pattern is shown by the map. As shown in FIG. 8, it turns out that the positional deviation amounts are especially large at the positions (points surrounded by the dotted lines) where the three pins 23 of the substrate cover 22 are arranged. This positional deviation is attributed to the potential distribution formed on the surface of the target object 2 by applying an electric potential to the target object 2 or the electrode substrate 20.

In the positional deviation correction map generating step (S208), the positional deviation correction map generation unit 40 reads the position data from the storage device 140, and generates a positional deviation correction map which defines a correction amount for correcting a positional deviation amount from the position of each design grid pattern. The positional deviation correction map defines, for example, a position deviated in the opposite direction to that of the positional deviation amount from each design grid pattern position and by the same amount as the positional deviation amount from the each design grid pattern position. The generated positional deviation correction map is stored in the storage device 140. The steps up to this step are carried out as preprocessing of the writing processing. Next, the target object 2 on which a pattern is actually to be written is placed on the XY stage 3, and then, the writing processing is started.

In the shot data generating step (S210), the shot data generation unit 41 reads writing data, from the storage device 140, for each stripe region (not shown) of the target object 2, for example. Then, by performing plural-stage data processing on the writing data, shot data for each shot is generated. The size of a figure pattern defined by the writing data is usually larger than the shot size which can be formed by one shot of the writing apparatus 100. Therefore, in the writing apparatus 100, each figure pattern is divided into a plurality of shot figures each having a size that can be formed by one shot of the writing apparatus 100. Each shot data defines, for example, a figure code indicating a shot figure, coordinates of a reference position of a shot figure, and the size of a shot figure.

In the positional deviation correcting step (S212), in the state where the electrode substrate 20 has a positive fixed potential with respect to the target object 2, the positional deviation correction unit 42 (a correction circuit) corrects a positional deviation of an electron beam on the surface of the target object 2 which occurs when the target object 2 is irradiated with the electron beam 6. Here, in the state where the electrode substrate 20 has a positive fixed potential with respect to the target object 2, the positional deviation correction unit 42 corrects a positional deviation attributed to the potential distribution formed on the surface of the target object 2. Specifically, it operates as follows: The positional deviation correction unit 42 reads a positional deviation correction map from the storage device 140. Then, for each shot, referring to the positional deviation correction map, the positional deviation correction unit 42 adds a correction amount relating to the position corresponding to coordinates defined by shot data, which is defined in the positional deviation correction map, to the coordinates defined by the shot data. Thereby, positional deviation of the irradiation position of the electron beam of each shot can be corrected.

In the fixed potential applying step (S214), the potential applying circuit 48 applies a voltage to the target object 2 or the electrode substrate 20 so that the electrode substrate 20 may have a positive fixed potential with respect to the target object 2. Here, for example, in the state where the target object 2 is connected to the ground, a positive constant voltage is applied to the electrode substrate 20. Thereby, an unchanging electric field where the electrode substrate 20 has a positive electric potential with respect to the target object 2 can be produced.

In the writing step (S216), under the control the writing control unit 30, the writing mechanism 150 writes a pattern on the target object 2 with an electron beam for which positional deviation has been corrected.

As described above, by correcting, in shot data, a positional deviation attributed to the potential distribution, it becomes possible to accurately apply an electron beam to a desired position in actual writing processing.

Although the case where a positional deviation is corrected by correcting shot data is described in the above example, it is not limited thereto. For example, it is also preferable that, in the deflection control circuit 130, an actual beam irradiation position of each shot is corrected by correcting a deflection amount of the deflector 13 by the amount of positional deviation.

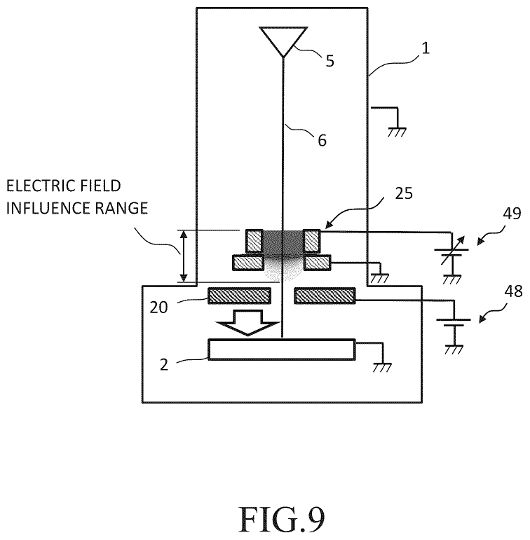

FIG. 9 is a diagram showing a part of the configuration of a writing apparatus according to a modified example of the first embodiment. In the example of FIG. 9, further, an electrostatic lens 25 is arranged in the electron optical column 1. Furthermore, an electrostatic lens control circuit 49 which controls the electrostatic lens 25 is arranged. The other configuration is the same as that of FIG. 1. In FIG. 9, configurations are omitted other than those required for explaining operations using the electrostatic lens 25. On the surface of the target object 2, there is surface asperity resulting from deflection, etc. due to its own weight. The electrostatic lens 25 dynamically corrects the focus position of the electron beam 6 according to a change of the height position of the target object surface which results from the asperity. FIG. 9 shows the case where the electrostatic lens 25 is composed of a two-stage electrode. As for the two-stage electrode, a variable positive potential is applied to the upper-stage electrode from the electrostatic lens control circuit 49, and the lower-stage electrode is connected to the ground. Here, as described above, if the influence of the electric field due to a variable potential applied to the upper-stage electrode exerts on the electric field on the surface of the target object 2, the potential distribution on the target object 2 surface changes during writing. Then, according to the first embodiment, the electrostatic lens 25 is arranged at a position such that the electric field between the electrode substrate 20 and the target object 2 is not included in the influence range of the electric field of the electrostatic lens 25. In other words, the electrostatic lens 25 is disposed upstream to the extent that the electric field between the electrode substrate 20 and the target object 2 is not affected. In further other words, the electrode substrate 20 is disposed at the position where the electric field due to the electrostatic lens 25 has been sufficiently attenuated. Thereby, even if dynamic focusing is performed using the electrostatic lens 25, the influence of the potential distribution on the surface of the target object 2 can be sufficiently suppressed.

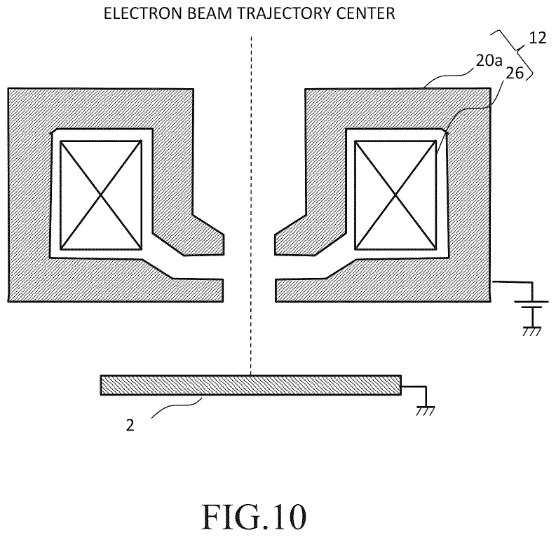

FIG. 10 is a diagram showing an example of a potential regulating member according to a modified example of the first embodiment. The objective lens 12 includes a coil 26 which surrounds the trajectory center of the electron beam 6, and a pole piece (also called a yoke) 20a (another example of the potential regulating member) of a ferromagnetic material which surrounds the coil 26. The pole piece 20a covers the inner and outer peripheral sides, and the upper and lower surface sides of the coil 26. Therefore, an opening trough which an electron beam passes is formed at the center part of the pole piece 20a. A gap is formed at the inner peripheral side of the pole piece 20a. When the coil 26 is excited, a magnetic field is generated by a magnetic flux passing through the inside of the pole piece 20a, and the magnetic field is emitted outside out of the gap. Thereby, the objective lens 12 forms a magnetic field on the electron beam trajectory.

For example, iron is used as a material of the pole piece 20a. The pole piece 20a is a conductive member while being a ferromagnetic material. Then, in the case of FIG. 10, the pole piece 20a of the objective lens 12 is used instead of the electrode substrate 20.

A positive constant voltage is applied from the potential applying circuit 48 so that the pole piece 20a may have a positive fixed potential with respect to the target object 2, and the target object 2 is connected to the ground through the pin 23 of the substrate cover 22 (not shown) in order to be a ground (GND) electric potential. Further, the electron optical column 1 is connected to the ground. Thereby, an unchanging electric field where the pole piece 20a has a positive potential with respect to the target object 2 is produced in the space between the pole piece 20a and the target object 2.

Alternatively, in order that the pole piece 20a may have a positive fixed potential with respect to the target object 2, in the state where the pole piece 20a is connected to the ground, a negative constant voltage is applied to the target object 2 from the potential applying circuit 48 through the pin 23 of the substrate cover 22 (not shown) so that the target object 2 may have a negative potential. Further, the electron optical column 1 is connected to the ground. Thereby, an unchanging electric field where the pole piece 20a has a positive potential with respect to the target object 2 is produced in the space between the pole piece 20a and the target object 2.

Although FIG. 10 shows the case where the bottom surface of the pole piece 20a is formed to be parallel to the upper surface of the target object 2, it is not limited thereto. The bottom surface of the pole piece 20a may be formed to be tapered diagonally downward to the center.

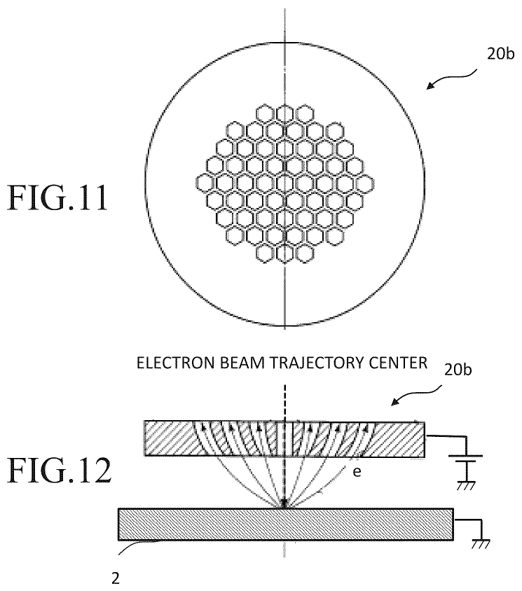

FIG. 11 is a top view showing another example of the potential regulating member according to a modified example of the first embodiment.

FIG. 12 is a sectional view showing another example of the potential regulating member and a target object according to a modified example of the first embodiment. In the examples of FIGS. 11 and 12, a conductive backscattered electron prevention plate 20b (another example of the potential regulating member) is disposed instead of the electrode substrate 20. The backscattered electron prevention plate 20b is formed with an outer diameter about the size covering the surface of the target object 2, for example, and, at its center part, an opening through which an electron beam passes. Further, in the periphery of the opening at the center part, a plurality of holes along the spiral trajectory of reflected electrons or secondary electrons are formed in order to lead a portion of the reflected electrons or the secondary electrons towards the upstream. Preferably, the plurality of holes are formed as right hexagons, for example, when viewed from the above. Accordingly, a honeycomb structure can be formed, thereby forming multiple holes. Thus, it becomes easy to enter secondary electrons, etc. emitted from the target object 2 to the plurality of holes, and therefore, the effect of reduction of secondary electrons, etc. which return to the target object 2 can be increased. Accordingly, the aperture area of the opening through which the center electron beam passes can be decreased.

A positive constant voltage is applied from the potential applying circuit 48 so that the backscattered electron prevention plate 20b may have a positive fixed potential with respect to the target object 2. The target object 2 is connected to the ground through the pin 23 of the substrate cover 22 (not shown) in order to be a ground (GND) electric potential. Further, the electron optical column 1 is connected to the ground. Thereby, an unchanging electric field where the backscattered electron prevention plate 20b has a positive potential with respect to the target object 2 is produced in the space between the backscattered electron prevention plate 20b and the target object 2.

Alternatively, the backscattered electron prevention plate 20b is connected to the ground to be a GND electric potential. A negative constant voltage is applied to the target object 2 from the potential applying circuit 48 through the pin 23 of the substrate cover 22 (not shown). Further, the electron optical column 1 is connected to the ground. Thereby, an unchanging electric field where the backscattered electron prevention plate 20b has a positive potential with respect to the target object 2 is produced in the space between the backscattered electron prevention plate 20b and the target object 2.

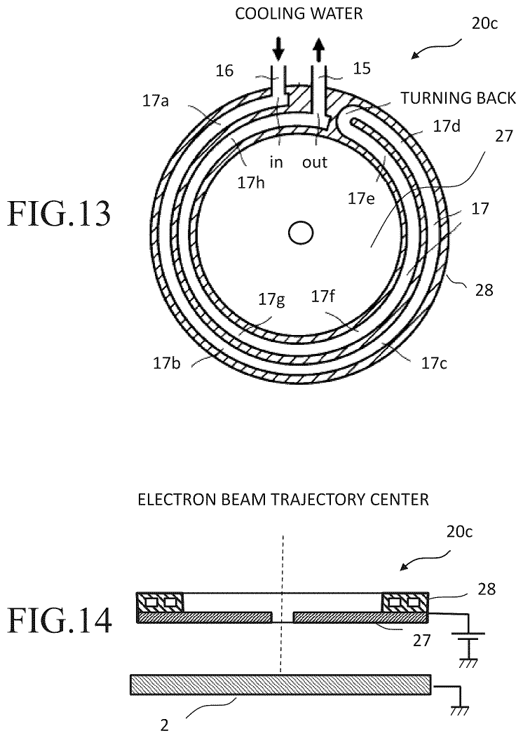

FIG. 13 is a top sectional view showing another example of the potential regulating member according to a modified example of the first embodiment.

FIG. 14 is a front sectional view showing another example of the potential regulating member and a target object according to a modified example of the first embodiment. In the examples of FIGS. 13 and 14, it is also preferable to use a thermal shielding mechanism 20c (another example of the potential regulating member) instead of the electrode substrate 20. The thermal shielding mechanism 20c includes a conductive soaking plate 27 and a conductive cooling tube 28. The soaking plate 27 is formed with an outer diameter about the size covering the surface of the target object 2, for example. At the center of the soaking plate 27, an opening through which an electron beam passes is formed. The cooling tube 28 is arranged on the soaking plate 27 so as to be along the periphery of the soaking plate 27. The cooling tube 28 can be formed to be divided into upper and lower parts. For example, it substantially goes round along the outer peripheral part from the upper surface side of the lower part, turns back at the position where one circle has substantially been completed, and engraves flow passages 17a to 17h which return along the outer peripheral part. Then, the upper and lower parts are connected together to be formed. Coolant flows into the cooling tube 28 from an inlet 16. The coolant flows along the outer peripheral part of the soaking plate 27, turns back at the position at the position where one circle has substantially completed, flows along the peripheral part, and is discharged from an outlet 15. Cooling water is used as the coolant. By arranging the thermal shielding mechanism 20c, it becomes possible to prevent exothermic heat due to excitation of the objective lens 12 from being transferred to the target object 2.

A positive constant voltage is applied from the potential applying circuit 48 to the thermal shielding mechanism 20c, and the target object 2 is connected to the ground through the pin 23 of the substrate cover 22 (not shown) in order to be a ground (GND) electric potential. Further, the electron optical column 1 is connected to the ground. Thereby, an unchanging electric field where the thermal shielding mechanism 20c has a positive potential with respect to the target object 2 is produced in the space between the thermal shielding mechanism 20c and the target object 2.

Alternatively, in order that the thermal shielding mechanism 20c may have a positive fixed potential with respect to the target object 2, in the state where the thermal shielding mechanism 20c is connected to the ground, a negative constant voltage is applied to the target object 2 from the potential applying circuit 48 through the pin 23 of the substrate cover 22 (not shown) so that the target object 2 may have a negative potential. Further, the electron optical column 1 is connected to the ground. Thereby, an unchanging electric field where the thermal shielding mechanism 20c has a positive potential with respect to the target object 2 is produced in the space between the thermal shielding mechanism 20c and the target object 2.

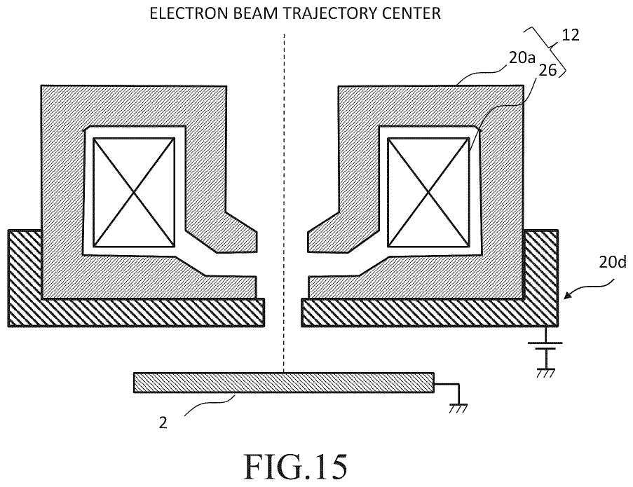

FIG. 15 is a sectional view showing another example of the potential regulating member and a target object according to a modified example of the first embodiment. In the example of FIG. 15, it is also preferable to use a conductive objective lens holding member 20d (another example of the potential regulating member) instead of the electrode substrate 20. The objective lens holding member 20d includes an outer peripheral frame and a bottom circular plate at the back side of the outer peripheral frame. An opening through which an electron beam passes is formed at the center part of the bottom circular plate. In the objective lens holding member 20d, the objective lens 12 is housed in the outer peripheral frame, and held on the upper surface of the bottom circular plate.

A positive constant voltage is applied from the potential applying circuit 48 so that the objective lens holding member 20d may have a positive fixed potential with respect to the target object 2, and the target object 2 is connected to the ground through the pin 23 of the substrate cover 22 (not shown) in order to be a ground (GND) electric potential. Further, the electron optical column 1 is connected to the ground. Thereby, an unchanging electric field where the objective lens holding member 20d has a positive potential with respect to the target object 2 is produced in the space between the objective lens holding member 20d and the target object 2.

Alternatively, in order that the objective lens holding member 20d may have a positive fixed potential with respect to the target object 2, in the state where the objective lens holding member 20d is connected to the ground, a negative constant voltage is applied to the target object 2 from the potential applying circuit 48 through the pin 23 of the substrate cover 22 (not shown) so that the target object 2 may have a negative potential. Further, the electron optical column 1 is connected to the ground. Thereby, an unchanging electric field where the objective lens holding member 20d has a positive potential with respect to the target object 2 is produced in the space between the objective lens holding member 20d and the target object 2.

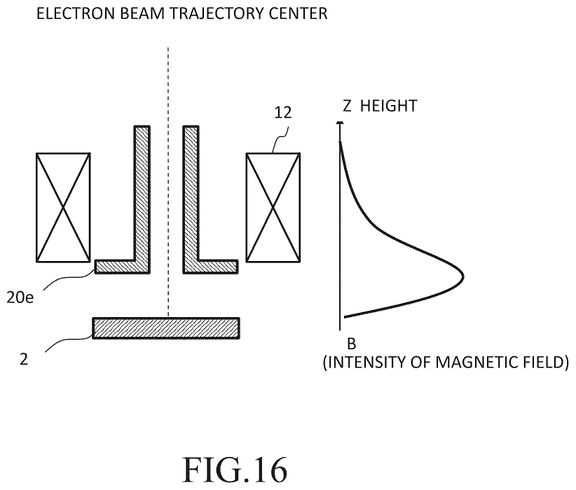

FIG. 16 is a sectional view showing another example of the potential regulating member and a target object according to a modified example of the first embodiment. In the example of FIG. 16, it is also preferable to use a conductive cylindrical electrode 20e (another example of the potential regulating member) instead of the electrode substrate 20. The cylindrical electrode 20e has a circular plate which extends, at the lower part of the cylindrical body, outwards from the outer peripheral part of the cylindrical body. The circular plate is formed with an outer diameter of the size covering the surface of the target object 2, for example. An opening of the same size as that of the inner diameter of the cylindrical body is formed at the center part of the circular plate. Electron beams pass through the inside of the cylindrical body and the inside of the opening of the circular plate. The cylindrical electrode 20e has a cylindrical body surface which extends, at the inner peripheral side of the objective lens 12 (electromagnetic lens), from the height position closer to the target object 2 side than to the objective lens 12 to the height position where the intensity of the magnetic field of the objective lens 12 is less than or equal to a threshold.

Specifically, the cylindrical body is formed to extend upstream to the place where the magnetic field of the objective lens is weaker than a threshold, and a Larmor radius of a secondary electron, etc. is small. Secondary electrons, etc. easily remain at the height position where the magnetic field is strong. Therefore, by extending the cylindrical body to the height position where the magnetic field is weak, it becomes possible to prevent secondary electrons, etc. from remaining and to decrease the space charge effect with respect to primary electron beams.

A positive constant voltage is applied from the potential applying circuit 48 so that the cylindrical electrode 20e may have a positive fixed potential with respect to the target object 2, and the target object 2 is connected to the ground through the pin 23 of the substrate cover 22 (not shown) in order to be a ground (GND) electric potential. Further, the electron optical column 1 is connected to the ground. Thereby, an unchanging electric field where the cylindrical electrode 20e has a positive potential with respect to the target object 2 is produced in the space between the cylindrical electrode 20e and the target object 2.

Alternatively, in the state where the cylindrical electrode 20e is connected to the ground so as to have a positive fixed potential with respect to the target object 2, a negative constant voltage is applied from the potential applying circuit 48 through the pin 23 of the substrate cover 22 (not shown) so that the target object 2 may have a negative potential. Further, the electron optical column 1 is connected to the ground. Thereby, an unchanging electric field where the cylindrical electrode 20e has a positive potential with respect to the target object 2 is produced in the space between the cylindrical electrode 20e and the target object 2.

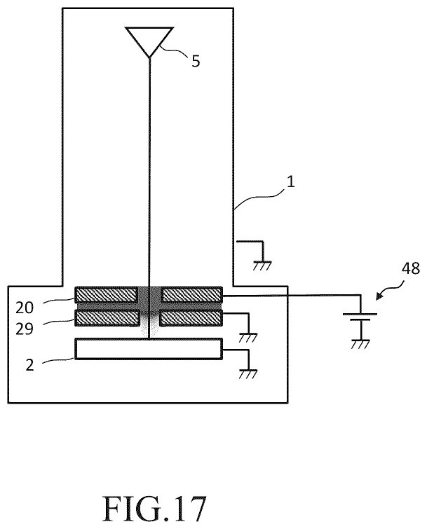

FIG. 17 is a diagram for explaining an example of an electric field between an electrode substrate and a target object according to a modified example of the first embodiment. In FIG. 17, an electrode substrate 29 being another potential regulating member is arranged between the electrode substrate 20 and the target object 2. Preferably, the outer diameter size of the electrode substrate 29 is equal to or greater than the electrode substrate 20. An opening through which electron beams pass is formed at the center part of the electrode substrate 29. It is preferable that the size of the opening of the electrode substrate 29 is equal to or less than that of the opening of the electrode substrate 20. It is furthermore preferable that the size of the opening of the electrode substrate 29 is smaller than that of the opening of the electrode substrate 20. The electrode substrate 29 is controlled to be equipotential with the target object 2.

A positive voltage is applied from the potential applying circuit 48 so that the electrode substrate 20 may have a positive fixed potential with respect to the target object 2, and the target object 2 is connected to the ground through the pin 23 of the substrate cover 22 (not shown) in order to be a ground (GND) electric potential. Similarly, a GND potential is applied to the electrode substrate 29. That is, the target object 2 and the electrode substrate 29 are connected to the ground. Further, the electron optical column 1 is connected to the ground. Thereby, an unchanging electric field where the electrode substrate 20 has a positive potential with respect to the electrode substrate 29 is produced in the space between the electrode substrate 20 and the electrode substrate 29. Then, this electric field leaks from the opening of the electrode substrate 29 to the target object 2 side. Thereby, an unchanging electric field where the electrode substrate 20 has a positive electric potential with respect to the target object 2 is produced at around the center part of the space between the electrode substrate 20 and the target object 2. By contrast, no electric field is produced at the outer peripheral part. Thereby, on the surface of the target object 2, the electric field distributes only in a small region at the central part, and the electric field disturbance due to the structure at the end of the target object 2 is reduced, and thus, a positional deviation amount can be reduced.

Alternatively, in the state where the electrode substrate 20 is connected to the ground so as to have a positive fixed potential with respect to the target object 2, a negative voltage is applied from the potential applying circuit 48 through the pin 23 of the substrate cover 22 (not shown) so that the target object 2 may have a negative potential. Similarly, a negative voltage is applied to the electrode substrate 29 from the potential applying circuit 48 so that it may be equipotential with the electrode substrate 20. Further, the electron optical column 1 is connected to the ground. Thereby, an unchanging electric field where the electrode substrate 20 has a positive potential with respect to the target object 2 is produced in the space between the electrode substrate and the target object 2.

As described above, according to the first embodiment, it is possible to correct a positional deviation highly precisely in electron beam writing while preventing emitted secondary electrons, etc. from returning to the target object.

### Second Embodiment

In a second embodiment, there is described a configuration for correcting deflection sensitivity of electron beams while preventing emitted secondary electrons, etc. from returning to the target object. The contents of the second embodiment are the same as those of the first embodiment except what is specifically described below.

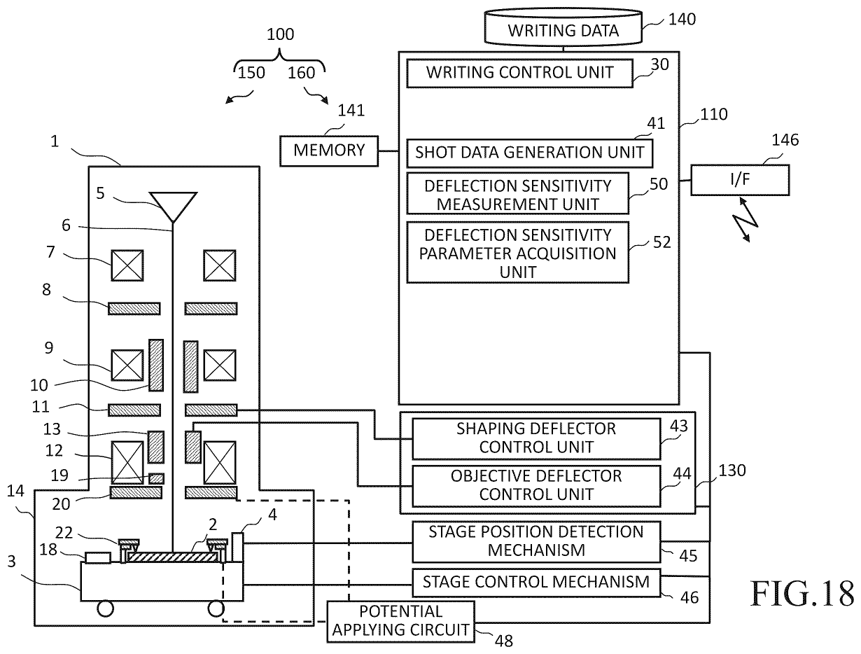

FIG. 18 is a block diagram showing an example of the configuration of a writing apparatus according to the second embodiment. The contents of FIG. 18 are the same as those of FIG. 1 except that a deflection sensitivity measurement unit 50 and a deflection sensitivity parameter acquisition unit 52 are arranged instead of the positional deviation correction map generation unit 40 and the positional deviation correction unit 42. Each of the “units” such as the writing control unit 30, the shot data generation unit 41, the deflection sensitivity measurement unit 50, and the deflection sensitivity parameter acquisition unit 52 includes processing circuitry. The processing circuitry includes an electric circuit, a computer, a processor, a circuit board, a quantum circuit, a semiconductor device, or the like. Each of the units may use common processing circuitry (the same processing circuitry), or different processing circuitry (separate processing circuitry). Input data required in the writing control unit 30, the shot data generation unit 41, the deflection sensitivity measurement unit 50, and the deflection sensitivity parameter acquisition unit 52, or calculated results are stored in the memory 141 each time.

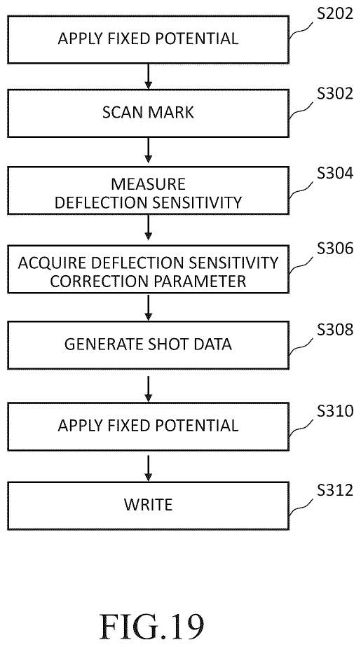

FIG. 19 is a flowchart showing an example of main steps of a writing method according to the second embodiment. In FIG. 19, the writing method of the second embodiment executes a series of steps: a fixed potential applying step (S202), a mark scanning step (S302), a deflection sensitivity measuring step (S304), a deflection sensitivity correction parameter acquiring step (S306), a shot data generating step (S308), a fixed potential applying step (S310), and a writing step (S312).

As described above, when a structure overlapping with a part of the target object 2 exists in the state where an electric field has been produced between the electrode substrate 20 and the target object 2, the potential of the surface of the target object 2 is not a constant value, and therefore, a potential distribution is generated on the surface of the target object 2. Thereby, a positional deviation may occur at the irradiation position of an electron beam. Such positional deviation can be regarded as generated attributed to deflection sensitivity of the electron beam. Then, according to the second embodiment, such positional deviation is corrected by correcting the deflection sensitivity of the electron beam 6.

In the fixed potential applying step (S202), the potential applying circuit 48 applies a predetermined voltage to the target object 2 or the electrode substrate so that the electrode substrate 20 may have a positive fixed potential with respect to the target object 2. Here, for example, in the state where the target object 2 is connected to the ground, a positive voltage is applied to the electrode substrate 20. Thereby, an unchanging electric field where the electrode substrate 20 has a positive electric potential with respect to the target object 2 can be produced.

In the mark scanning step (S302), first, the XY stage 3 is moved so that the center of the mark 18 may be located at the deflection center of the deflector 13. For example, if the electron beam 6 is applied along the trajectory central axis of the electron beam 6 in the state where the electron beam 6 is not deflected at all by the deflector 13, the deflection center of the deflector 13 serves as the trajectory central axis of the electron beam 6. In such a case, the XY stage 3 is moved so that the center of the mark 18 may be located at the trajectory central axis of the electron beam 6.

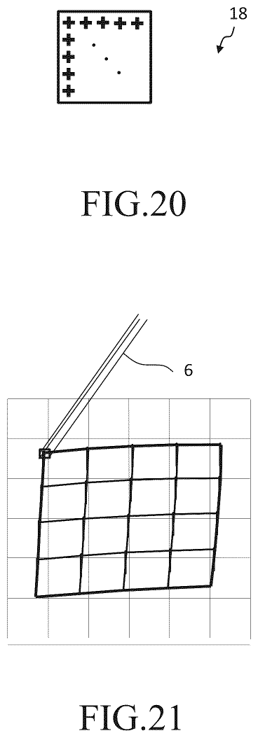

FIG. 20 is a diagram showing an example of a mark according to the second embodiment. FIG. 20 shows the case where a plurality of cross patterns are formed in the mark 18. As the plurality of cross patterns, 5×5 cross patterns are arranged, for example. It is preferable that the circumferential size of the 5×5 cross patterns is set to be the size of the deflection region of the deflector 13 which deflects the electron beam 6 to the target object 2. In other words, the inside of the deflection region on the target object 2 surface of the deflector 13 is divided into a plurality of (5×5) grid positions, and, in the mark 18, cross patterns are formed to be corresponding to each position in the deflection region of the deflector 13.

The writing mechanism 150 scans each cross pattern in the mark in order with the electron beam 6 by using the deflector 13. At that time, the detector 19 detects a secondary electron emitted from the mark 18. Information detected at each position is output to the control computer 110 through a detection circuit (not shown).

In the deflection sensitivity measuring step (S304), the deflection sensitivity measurement unit 50 calculates each of positions of a plurality of detected cross patterns, and measures deflection sensitivity of the electron beam 6 in the state where a fixed potential has been applied to the target object 2 or the electrode substrate 20.

FIG. 21 is a diagram showing an example of deflection sensitivity according to the second embodiment. FIG. 21 shows each measured position (thick line) superimposed on each design position. As shown in FIG. 20, it turns out that, from the potential distribution on the surface of the target object 2, a distortion occurs in the deflection sensitivity of the electron beam 6.

In the deflection sensitivity correction parameter acquiring step (S306), the deflection sensitivity parameter acquisition unit 52 (another example of the correction circuit) corrects a positional deviation by correcting the deflection sensitivity of an electron beam. Specifically, the deflection sensitivity parameter acquisition unit 52 (another example of the correction circuit) calculates a correction parameter for correcting a deviation between each design position and each position of measured deflection sensitivity. Such a correction parameter serves as a deflection sensitivity correction parameter. For example, coordinates (x,y) of a design position to be deflected are corrected in a direction opposite to the deviation direction by the amount of deviation by a third-order polynomial. It is preferable to calculate a deflection sensitivity correction parameter as a coefficient of each term of the third-order polynomial. An obtained deflection sensitivity correction parameter is output to the objective deflector control unit 44 to be set therein.

The steps described above are performed as preprocessing of the writing processing. Next, the target object 2 on which a pattern is actually to be written is arranged on the XY stage 3. Then, the writing processing is started.

In the shot data generating step (S308), the shot data generation unit 41 reads writing data, from the storage device 140, for each stripe region (not shown) of the target object 2, for example. Then, by performing plural-stage data processing on the writing data, shot data for each shot is generated. Each shot data defines, for example, a figure code indicating a shot figure, coordinates of a reference position of a shot figure, and the size of a shot figure.

In the fixed potential applying step (S310), the potential applying circuit 48 applies a constant voltage to the target object 2 or the electrode substrate 20 so that the electrode substrate 20 may have a positive fixed potential with respect to the target object 2. Here, for example, in the state where the target object 2 is connected to the ground, a positive voltage is applied to the electrode substrate 20. Thereby, an unchanging constant electric field where the electrode substrate 20 has a positive electric potential with respect to the target object 2 can be produced.

In the writing step (S312), since an acquired deflection sensitivity correction parameter has been set in the objective deflector control unit 44, the objective deflector control unit 44 deflects, for each shot, the electron beam 6 to the position where deflection sensitivity has been corrected. Under the control of the writing control unit 30, the writing mechanism 150 writes a pattern on the target object 2 with the electron beam whose positional deviation has been corrected.

As described above, according to the second embodiment, in electron beam writing, positional deviation of an electron beam can be corrected by correcting a deflection sensitivity while preventing emitted secondary electrons, etc. from returning to target object.

### Third Embodiment

In a third embodiment, there is described a configuration for correcting a positional deviation attributed to a charge amount charged by irradiation with electron beams on the resist surface of the target object 2. The contents of the third embodiment are the same as those of the first embodiment except what is specifically described below.

When the target object 2 is irradiated with electron beams, the irradiated position and its peripheral region are charged with electron beams having been previously applied. Conventionally, with respect to positional deviation due to such a charging phenomenon, there has been proposed a method for correcting a charging effect by calculating the amount of correction of a beam irradiation position by acquiring a charge amount distribution, and applying a beam to the position corrected based on the correction amount. However, in a state where an unchanging constant electric field has been produced in which the electrode substrate 20 has a positive electric potential with respect to the target object 2, the behavior of the charge amount may be different from the conventional state where no electric field is produced. Then, according to the third embodiment, by acquiring the behavior of the charge amount in the state where an unchanging constant electric field has been produced in which the electrode substrate 20 has a positive electric potential with respect to the target object 2, the positional deviation attributed to the charge amount is corrected.

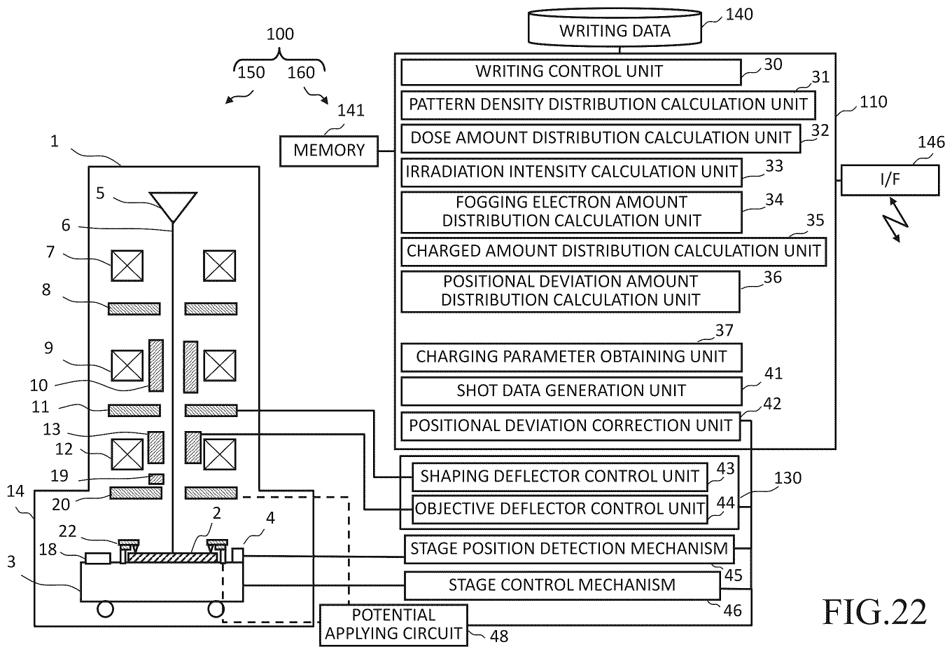

FIG. 22 is a block diagram showing an example of the configuration of a writing apparatus according to the third embodiment. In FIG. 22, instead of the positional deviation correction map generation unit 40, there arranged a pattern area density distribution calculation unit 31, a dose amount distribution calculation unit 32, an irradiation intensity calculation unit 33, a fogging electron amount distribution calculation unit 34, a charge amount distribution calculation unit 35, a positional deviation amount distribution calculation unit 36, and a charging parameter acquisition unit 37. The other configuration is the same as that of FIG. 1.

Each of the “units” such as the writing control unit 30, the pattern area density distribution calculation unit 31, the dose amount distribution calculation unit 32, the irradiation intensity calculation unit 33, the fogging electron amount distribution calculation unit 34, the charge amount distribution calculation unit 35, the positional deviation amount distribution calculation unit 36, the charging parameter acquisition unit 37, the shot data generation unit 41, and the positional deviation correction unit 42 includes processing circuitry. The processing circuitry includes an electric circuit, a computer, a processor, a circuit board, a quantum circuit, a semiconductor device, or the like. Each of the “units” may use common processing circuitry (the same processing circuitry), or different processing circuitry (separate processing circuitry). Input data required in the writing control unit 30, the pattern area density distribution calculation unit 31, the dose amount distribution calculation unit 32, the irradiation intensity calculation unit 33, the fogging electron amount distribution calculation unit 34, the charge amount distribution calculation unit 35, the positional deviation amount distribution calculation unit 36, the charging parameter acquisition unit 37, the shot data generation unit 41, and the positional deviation correction unit 42, or calculated results are stored in the memory 141 each time.

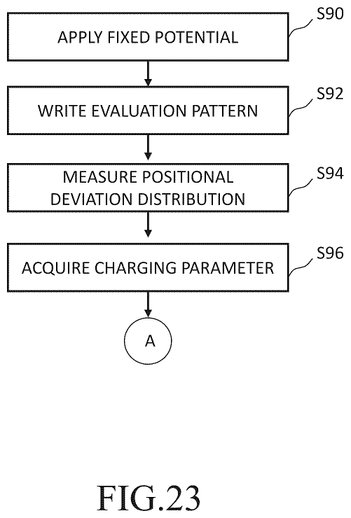

FIG. 23 is a flowchart showing a part of an example of main steps of a writing method according to the third embodiment.

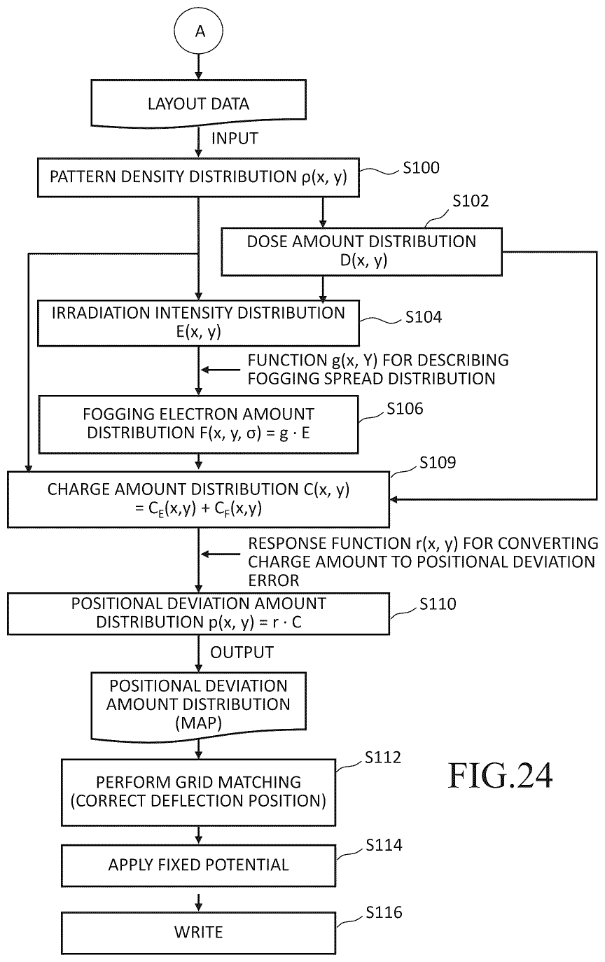

FIG. 24 is a flowchart showing a part of an example of main steps of a writing method according to the third embodiment. In FIGS. 23 and 24, the writing method of the third embodiment executes a series of steps: a fixed potential applying step (S90), an evaluation pattern writing step (S92), a positional deviation distribution measuring step (S94), a charging parameter acquiring step (S96), a pattern area density distribution ρ(x,y) calculating step (S100), a dose amount distribution D(x,y) calculating step (S102), an irradiation intensity distribution E(x,y) calculating step (S104), a fogging electron amount distribution F(x,y,σ) calculating step (S106), a charge amount distribution C(x,y) calculating step (S109), a positional deviation amount distribution p(x,y) calculating step (S110), a deflection position correcting step (S112), a fixed potential applying step (S114), and a writing step (S116).

In the fixed potential applying step (S90), the potential applying circuit 48 applies a voltage to the target object 2 or the electrode substrate 20 so that the electrode substrate 20 may have a positive fixed potential with respect to the target object 2. Here, for example, in the state where the target object 2 is connected to the ground, a positive constant voltage is applied to the electrode substrate 20. Thereby, an unchanging constant electric field where the electrode substrate 20 has a positive electric potential with respect to the target object 2 can be produced.

Then, acquired is a parameter (charging parameter) of a polynomial which defines a charge amount in the state where an unchanging constant electric field has been produced in which the electrode substrate 20 has a positive electric potential with respect to the target object 2. It is specifically described below.

In the evaluation pattern writing step (S92), the writing mechanism 150 writes an evaluation pattern, which is used for evaluating a positional deviation attributed to the charge amount, on an evaluation substrate coated with resist.

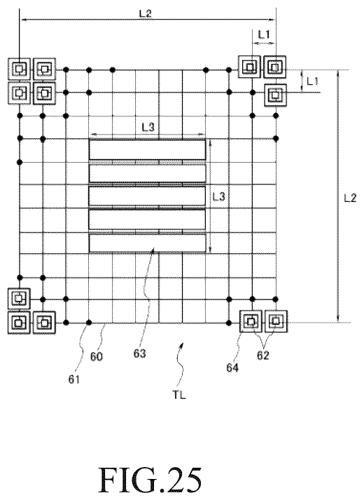

FIG. 25 is a diagram showing an example of an evaluation pattern according to the third embodiment. The test layout TL (evaluation pattern) shown in FIG. 25 can be acquired by writing a first box array 62 with, for example, a dose of 12 μC/cm² on a grid (81×81 grids) 60 whose pitch L1 is 1 mm and side length L2 is 80 mm, then writing an irradiation pad 63 whose side length L3 is 40 mm and pattern density is 100% with, for example, a dose of 21 μC/cm² in the center of the layout TL, and further writing a second box array 64 with a dose of 12 μC/cm² on the same grid 60 as that of the first box array 62.

The first box array 62 is, for example, a square pattern whose side length is 4 μm. The second box array 64 in which an opening larger than the first box array 62 is formed at the center is a frame type pattern whose side length is, for example, 14 μm.

The test layout TL is formed changing the pattern density of the irradiation pad 63 to be 100%, 75%, 50%, 25%, and so on.

The irradiation pad 63 is composed of a plurality of rectangular patterns having a space in between each other. This space is 20 μm, for example.

In the positional deviation distribution measuring step (S94), a positional deviation of the evaluation pattern is measured to generate a positional deviation distribution. Specifically, it operates as follows: A resist pattern is formed by taking out the evaluation substrate from the writing apparatus 100, and performing asking for it. The positions of the first and second box arrays 62 and 64 are individually measured from the obtained resist pattern by a position measuring device (not shown). Then, a positional deviation of the irradiation pad 63 caused by a charging effect can be measured by subtracting the position of the first box array 62 from that of the second box array 64. In the third embodiment, in order to shorten the measuring time, positional deviations of the two box arrays 62 and 64 written on the grid 61 of 41×41 grids whose pitch is 2 mm are measured in the 81×81 grids shown in FIG. 25.

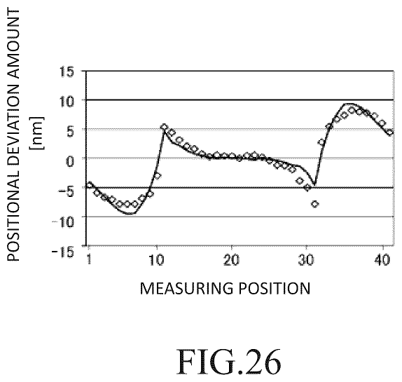

FIG. 26 is a diagram showing an example of a positional deviation distribution according to the third embodiment. FIG. 26 shows, for example, an x-direction positional deviation at a predetermined position in the y direction. In FIG. 26, a positional deviation amount of an irradiation position is shown at the center part, and positional deviation amounts of non-irradiation regions are shown at both the sides. The border between the irradiation region and the non-irradiation region exists in the vicinity of each of the two inflection points at the center part.

Similarly to the conventional charge effect correction method, a positional deviation amount distribution p(x,y) can be defined by performing a convolution integral of the response function r with a charge amount distribution C(x,y). As the response function r, the one used in the conventional charge effect correction method can be used. Alternatively, the response function r can be set by simulation, experiment, or the like. Then, according to the third embodiment, the coefficient of the polynomial serving as a model of the charge amount distribution C(x,y) is obtained as a charging parameter.

In the charging parameter acquiring step (S96), the charging parameter acquisition unit 37 acquires a charging parameter of the charge amount distribution C(x,y), using a result of measuring a positional deviation of the evaluation pattern.

First, the dose amount distribution D(x,y) is defined. For calculating a dose amount, it is preferable to perform a correction of a proximity effect due to backscattered electrons. The dose amount D can be defined by the following equation (1).

D=D₀×{(1+2×η)/(1+2×η×ρ)} (1)

In the equation (1), D₀ indicates a reference dose amount, and η indicates a backscattering rate.

The reference dose D₀ and the backscattering rate η are set by the user of the writing apparatus 100 concerned. The backscattering rate η can be set in consideration of the acceleration voltage of the electron beam 6, the resist thickness and ground substrate type of the target object 2, the process conditions (e.g., PEB conditions and developing conditions) and the like.

Next, the irradiation intensity distribution E(x,y) of each mesh region is defined by multiplying each value of the pattern density distribution ρ(x,y) by a corresponding position value of the dose amount distribution D(x,y). The following equation (2) defines the irradiation intensity distribution E(x,y).

E(x,y)=ρ(x,y)D(x,y) (2)

Next, a fogging-electron-amount distribution F(x,y,σ) (fogging-charged-particle-amount distribution) (=E·g) is defined by performing a convolution integral of a fogging electron distribution function g(x,y) and the irradiation intensity distribution E(x,y) described above. It is specifically described below.

First, the distribution function g(x,y) indicating a spread distribution of a fogging electron can be defined by the following equation (3), using an influence radius σ of the fogging effect. Here, Gaussian distribution is used as an example.

g(x,y)=(1/Πσ²)×exp{−(x²+y²)/σ²} (3)

The fogging-electron-amount distribution F(x,y,σ) can be defined by the following equation (4).

F(x,y,σ)=∫∫g(x−x′,y−y′)E(x′,y′)dx′dy′ (4)

A function C(E,F) for obtaining a charge amount distribution C(x,y) is assumed. Specifically, the charge amount distribution C(x,y) is defined by a model using a function C_{E}(E) of an irradiation region contributed by irradiation electrons, and a function C_{F}(F) of a non-irradiation region contributed by fogging electrons. The charge amount distribution C(x,y) is defined by the following equation (5), for example.

$$C ( x , y ) = C ( E , F ) = {C}_{E} ( E ) + {C}_{F} ( F ) = {d}_{0} + {d}_{1} \times p + {d}_{2} \times D + {d}_{3} \times E + {e}_{1} \times F + {e}_{2} \times {F}^{2} + {e}_{3} \times {F}^{3} \qquad ( 5 )$$

The model of the charge amount distribution C(x,y) is not limited to this. For example, it is also preferable to use a polynomial model further combined with at least one of a peak function having a peak (local maximum point) of the charge amount, a linear function, and a convergence function in which the charge amount converges at infinity.

Assuming that the positional deviation amount distribution p(x,y) can be defined by a model which performs a convolution integral of the response function r with the charge amount distribution C(x,y), the charging parameter acquisition unit 37 calculates a combination of parameters d₀, d₁, d₂, d₃, e₁, e₂, and e₃ that is most coincident with the positional deviation amount measured in the state of the unchanging constant electric field where the electrode substrate 20 has a positive electric potential with respect to the target object 2. Such combination of the parameters d₀, d₁, d₂, d₃, e₁, e₂, and e₃ is stored as a charging parameter in the storage device 140.

The steps up to this step are carried out as preprocessing of the writing processing. Next, the target object 2 on which a pattern is actually to be written is placed on the XY stage 3, and then, the writing processing is started.

When writing a pattern defined by writing data on the target object 2 to be actually written, a positional deviation map attributed to a charge amount is generated. Specifically, it operates as follows:

In the pattern area density distribution ρ(x,y) calculating step (S100), the pattern area density distribution calculation unit 31 reads writing data from the storage device 140, and calculates a pattern density ρ(x,y) indicating a coverage rate of a figure pattern defined by the writing data, for each mesh region obtained by virtually dividing the writing region into a plurality of mesh regions by a prescribed dimension. Then, a distribution ρ(x,y) of a pattern density for each mesh region is generated.

In the dose amount distribution D(x,y) calculating step (S102), the dose amount distribution calculation unit 32 calculates a distribution D(x,y) of the dose amount for each mesh region, using a pattern density distribution ρ(x,y). In calculating the dose amount, it is preferable to perform a correction of a proximity effect due to backscattered electrons. The dose amount D can be defined by the equation (1).

In the irradiation intensity distribution E(x,y) calculating step (S104), the irradiation intensity calculation unit 33 calculates an irradiation intensity distribution E(x,y) of each mesh region by multiplying each mesh value of the pattern density distribution ρ(x,y) by a corresponding mesh value of the dose amount distribution D(x,y). The irradiation intensity distribution E(x,y) can be defined by the equation (2).

In the fogging electron amount distribution F(x,y,σ) calculating step (S106), the fogging electron amount distribution calculation unit 34 (fogging charged particle amount distribution calculation unit) calculates a fogging electron amount distribution F(x,y,σ) (fogging charged particle amount distribution) (=E·g) by performing a convolution integral of a fogging electron distribution function g(x,y) and the irradiation intensity distribution E(x,y) calculated in the irradiation intensity distribution E(x,y) calculating step described above. The fogging electron amount distribution F(x,y,σ) can be defined by the equation (4).

In the charge amount distribution C(x,y) calculating step (S109), the charge amount distribution calculation unit 35 calculates a charge amount distribution C(x,y) in the state of the unchanging constant electric field where the electrode substrate 20 has a positive electric potential with respect to the target object 2, using the irradiation intensity distribution E(x,y) and the fogging electron amount distribution F(x,y,σ). The charge amount distribution C(x,y) can be defined by the equation (5). The acquired charging parameter is used for calculation of the charge amount distribution C(x,y).

In the positional deviation amount distribution p(x,y) calculating step (S110), the positional deviation amount distribution calculation unit 36 calculates, using an acquired charge amount distribution C(x,y), a positional deviation amount of an irradiation pattern attributed to the charge amount in the state of the unchanging constant electric field where the electrode substrate 20 has a positive electric potential with respect to the target object 2. Specifically, the positional deviation amount distribution calculation unit 36 calculates a positional deviation amount P of the writing position (x,y) attributed to the charge amount of each position (x,y) in the charge amount distribution C(x,y) by performing a convolution integral of a response function r(x,y) with each charge amount C of the charge amount distribution C(x,y). A response function r(x,y) is assumed which converts the charge amount distribution C(x,y) into the positional deviation amount distribution p(x,y). Here, a charge position indicated by each position in the charge amount distribution C(x,y) is expressed by (x′,y′), and a beam irradiation position in a stripe region being data-processed is expressed by (x,y). Since here the beam positional deviation can be represented as a function of the distance from a beam irradiation position (x,y) to a charge position (x′,y′), it is possible to express the response function as r(x-x′,y-y′). The response function r(x-x′,y-y′) may be obtained in advance from an experiment such that it fits the experiment result. Hereinafter, in the first embodiment, (x,y) indicates a beam irradiation position of a stripe region being data-processed.

Then, the positional deviation amount distribution calculation unit 36 generates a positional deviation amount distribution Pi(x,y) (or called a positional deviation amount map Pi(x,y)), based on the positional deviation amount P of each position (x,y) to be written in the stripe region concerned. The calculated positional deviation amount map Pi(x,y) is stored in the storage device 140.

On the other hand, the shot data generation unit 41 reads writing data from the storage device 140, and performs plural-stage data conversion processing in order to generate shot data in a format specific to the writing apparatus 100. The size of a figure pattern defined by the writing data is usually larger than the shot size which can be formed by one shot by the writing apparatus 100. Therefore, each figure pattern is divided into a plurality of shot figures each having a size that can be formed by one shot of the writing apparatus 100. Then, for each shot, data such as a figure code indicating a figure type, coordinates, and size are defined.

In the deflection position correcting step (S112), the positional deviation correction unit 42 corrects an irradiation position, using a positional deviation amount. Here, shot data of each position is corrected. Specifically, a correction value for correcting a positional deviation amount shown in the positional deviation amount map Pi(x,y) is added to each position (x,y) of the shot data. For example, it is preferable to use, as the correction value, a value obtained by reversing the positive and negative signs of the positional deviation amount shown in the positional deviation amount map Pi(x,y). Thereby, since the coordinates of the irradiation target are corrected when irradiated with the electron beam 6, the deflection position to be deflected by the objective deflector 13 is corrected. The shot data is defined in the order of shots in the data file.

In the fixed potential applying step (S114), the potential applying circuit 48 applies a constant voltage to the target object 2 or the electrode substrate 20 so that the electrode substrate 20 may have a positive fixed potential with respect to the target object 2. Here, for example, in the state where the target object 2 is connected to the ground, a positive voltage is applied to the electrode substrate 20. Thereby, an unchanging constant electric field where the electrode substrate 20 has a positive electric potential with respect to the target object 2 can be produced.

In the writing step (S116), in the deflection control circuit 130, the shaping deflector control unit 43 calculates, for each shot figure, in the order of shots, a deflection amount of the shaping deflector 10 for variably shaping the electron beam 6, based on the figure type and size defined by the shot data. At the same time, the objective deflector control unit 44 calculates a deflection amount of the deflector 13 for deflecting the shot FIG. concerned to the position to be irradiated on the target object 2. In other words, the objective deflector control unit 44 calculates a deflection amount for deflecting an electron beam to a corrected irradiation position. The electron optical column 1 emits an electron beam to the corrected irradiation position. Specifically, the deflector 13 disposed in the electron optical column 1 deflects an electron beam based on the calculated deflection amount in order to apply an electron beam to the corrected irradiation position. Thereby, the writing mechanism 150 writes a pattern at a charge-corrected position on the target object 2, in the state of an unchanging constant electric field where the electrode substrate 20 has a positive potential with respect to the target object 2.

As described above, according to the third embodiment, it is possible in electron beam writing to correct a positional deviation of an electron beam attributed to a charge amount while preventing emitted secondary electrons, etc. from returning to the target object 2.

### Fourth Embodiment

In each of the Embodiments described above, a positional deviation correction is applied to a writing apparatus using a single beam, but it is not limited thereto. The fourth embodiment describes the case of applying a positional deviation correction to a writing apparatus using multiple beams. For example, it is also preferable to use a writing apparatus using multiple beams as the writing apparatus of the first embodiment. The fourth embodiment describes the case of applying a charge effect correction, for example.

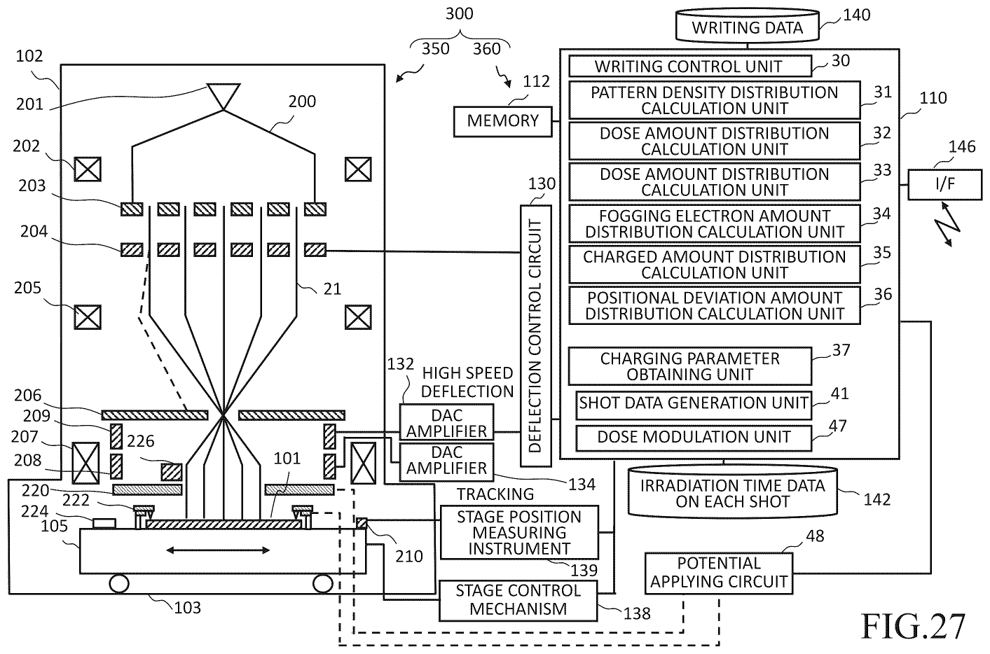

FIG. 27 is a conceptual diagram showing the configuration of a writing apparatus according to the fourth embodiment. In FIG. 27, a writing apparatus 300 includes a writing mechanism 350 and a control system circuit 360. The writing apparatus 300 is an example of a multiple electron beam writing apparatus, and an example of a multiple electron beam exposure apparatus. The writing mechanism 350 includes an electron optical column 102 and a writing chamber 103. In the electron optical column 102, there are disposed an electron gun 201, an illumination lens 202, a shaping aperture array substrate 203, a blanking aperture array mechanism 204, a reducing lens 205, a limiting aperture member 206, an objective lens 207, deflectors 208 and 209, an electrode substrate 220, and a detector 226.

In the writing chamber 103, an XY stage 105 is disposed. On the XY stage 105, there is placed a target object 101 such as a mask serving as a writing target substrate when writing is performed. The target object 101 includes an exposure mask used when fabricating semiconductor devices, or a semiconductor substrate, etc. for fabricating semiconductor devices. Further, the target object 101 includes a mask blank on which resist has been applied and nothing has yet been written. On the XY stage 105, a mirror 210 for measuring the position of the XY stage 105 is further placed. Moreover, on the XY stage 105, a mark 224 is arranged at a position different from the position where the target object 101 is arranged. The surface of the mark 224 is flush with the surface of the target object 101.

Furthermore, on the XY stage 105, there is disposed a substrate cover 222 which covers the outer peripheral part of the target object 101. The substrate cover 222 has a plurality of pins which pierce the outer peripheral part of the target object 101 from the above to penetrate through the resist film and to be electrically connected to the conductive light shielding film made of, for example, chromium, etc. arranged beneath the resist film.

The control system circuit 360 includes the control computer 110, a memory 112, the deflection control circuit 130, digital-to-analog conversion (DAC) amplifier units 132 and 134, a stage control mechanism 138, a stage position measuring instrument 139, the external interface (I/F) circuit 146, the potential applying circuit 48, and storage devices 140 and 142 such as a magnetic disk drive. The control computer 110, the memory 112, the deflection control circuit 130, the stage control mechanism 138, the stage position measuring instrument 139, the external I/F circuit 146, the potential applying circuit 48, and the storage devices 140 and 142 are connected with each other through a bus (not shown). Writing data is input to the storage device 140 from the outside of the writing apparatus 300, and stored therein. To the deflection control circuit 130, the DAC amplifier units 132 and 134 and the blanking aperture array mechanism 204 are connected through a bus (not shown). The stage position measuring instrument 139 applies a laser light to the mirror 210 on the XY stage 105, and receives a reflected light from the mirror 210 in order to measure the position of the XY stage 105, using information on interference between the incident light and the reflected light.

The configuration in the control computer 110 is the same as that of FIG. 22 except that a dose modulation unit 47 (another example of the correction circuit) is disposed instead of the positional deviation correction unit 42.

Each of the “units” such as the writing control unit 30, the pattern area density distribution calculation unit 31, the dose amount distribution calculation unit 32, the irradiation intensity calculation unit 33, the fogging electron amount distribution calculation unit 34, the charge amount distribution calculation unit 35, the positional deviation amount distribution calculation unit 36, the charging parameter acquisition unit 37, the shot data generation unit 41, and the dose modulation unit 47 includes processing circuitry. The processing circuitry includes an electric circuit, a computer, a processor, a circuit board, a quantum circuit, a semiconductor device, or the like. Each of the “units” may use common processing circuitry (the same processing circuitry), or different processing circuitry (separate processing circuitry). Input data required in the writing control unit 30, the pattern area density distribution calculation unit 31, the dose amount distribution calculation unit 32, the irradiation intensity calculation unit 33, the fogging electron amount distribution calculation unit 34, the charge amount distribution calculation unit 35, the positional deviation amount distribution calculation unit 36, the charging parameter acquisition unit 37, the shot data generation unit 41, and the dose modulation unit 47, or calculated results are stored in the memory 141 each time.

FIG. 27 shows a configuration necessary for describing the fourth embodiment. Other configuration elements generally necessary for the writing apparatus 300 may also be included therein.

In the shaping aperture array substrate 203, holes of (p rows arrayed in the y direction)×(q columns arrayed in the x direction) (p≥2, q≥2) are formed like a matrix at a predetermined arrangement pitch. For example, holes of 512×512 are arranged length and width wise (x and y directions). Each of the holes is a rectangle having the same dimension and shape as each other. In the blanking aperture array mechanism 204, there are formed passage holes, through each of which each of multiple beams passes, at positions corresponding to the plurality of holes formed in a matrix form in the shaping aperture array substrate 203. Then, a pair of a control electrode and a counter electrode, for blanking deflection, which is called a blanker as a unit, is arranged in the vicinity of and across each passage hole. Further, close to each passage hole, there is arranged a control circuit for applying a deflection voltage to the control electrode. The counter electrode is connected to the ground. The electron beam passing through each passage hole is deflected by a voltage independently applied to the pair of the control electrode and the counter electrode. Blanking control is provided by this deflection. Blanking deflection is performed for each corresponding beam of the multiple beams. An individual blanking mechanism is composed of a pair of the control electrode and the counter electrode and its control circuit which are arranged for each passage hole. Thus, a plurality of blankers individually perform blanking deflection of a corresponding beam of the multiple beams having passed through the plurality of holes in the shaping aperture array substrate 203.

According to the fourth embodiment, blanking control of each beam is performed by beam ON/OFF control by each control circuit for individual blanking control described above. The writing operation of the fourth embodiment is proceeded for each stripe region as described above.

The electron beam 200 emitted from the electron gun 201 almost perpendicularly illuminates the whole of the shaping aperture array substrate 203 by the illumination lens 202. A plurality of rectangular holes are formed in the shaping aperture array substrate 203, and the region including all of the plurality of holes is irradiated with the electron beam 200. A plurality of electron beams (multiple beams) 21 are formed by the plurality of holes irradiated with the electron beam 200. Each beam of the multiple beams 21 is formed by an electron passing through each hole in the shaping aperture array substrate 203. The holes are formed in the shaping aperture array substrate 203 and each of them is rectangular, for example. The multiple beams 21 individually pass through corresponding blankers (individual blanking mechanism) of the blanking aperture array mechanism 204. The blanker is controlled by the deflection control circuit 130 and the control circuit of an individual blanking mechanism, and keeps at least a beam ON and OFF condition of corresponding beam of the multiple beams 21 which individually pass during a set writing time (irradiation time). In other words, the blanking aperture array mechanism 204 controls the irradiation time of the multiple beams.

The multiple beams 21 having passed through the blanking aperture array mechanism 204 are reduced by the reducing lens 205, and travel toward the hole in the center of the limiting aperture member 206. Then, beams which were deflected by the blanker of the blanking aperture array mechanism 204 in the multiple beams 21 deviate from the hole in the center of the limiting aperture member 206, and are blocked by the limiting aperture member 206. By contrast, other beams which were not deflected by the blanker of the blanking aperture array mechanism 204 pass through the hole in the center of the limiting aperture member 206 as shown in FIG. 27. Thus, the limiting aperture member 206 blocks each beam which was deflected to be in the OFF state by the individual blanking mechanism. Then, one shot of each beam is formed by a beam which has been made during a period from becoming beam ON to becoming beam OFF and has passed through the limiting aperture member 206.

The multiple beams 21 having passed through the limiting aperture member 206 are focused by the objective lens 207 so as to be a pattern image of a desired reduction ratio. Then, they are collectively deflected by the deflectors 208 and 209 in order to irradiate respective beam irradiation positions on the target object 101. The deflector 208 is controlled by a deflection voltage from the DAC amplifier unit 134. The deflector 209 is controlled by a deflection voltage from the DAC amplifier unit 132. Respective beams (all the multiple beams 21) having passed through the limiting aperture member 206 are collectively deflected in the same direction by the deflectors 208 and 209.

When, for example, the XY stage 105 is continuously moving, the beam irradiation position is controlled by the deflector 208 so that it may follow the movement of the XY stage 105. Ideally, the multiple beams 21 irradiating at a time are aligned at the pitch obtained by multiplying the arrangement pitch of a plurality of holes in the shaping aperture array substrate 203 by the desired reduction ratio described above. Thus, the electron optical column 102 (column) applies multiple beams onto the target object 101.

The XY stage 105 is driven by the stage control mechanism 138. The position of the XY stage 105 is detected by the stage position measuring instrument 139. The stage position measuring instrument 139 includes, for example, a laser length measuring device which applies a laser to the mirror 210 and measures the position, based on laser interference between an incident light and a reflected light.

In addition, the focus position of the multiple beams 21 may be dynamically corrected by an electrostatic lens (not shown), depending on asperity of the surface of the target object 101.

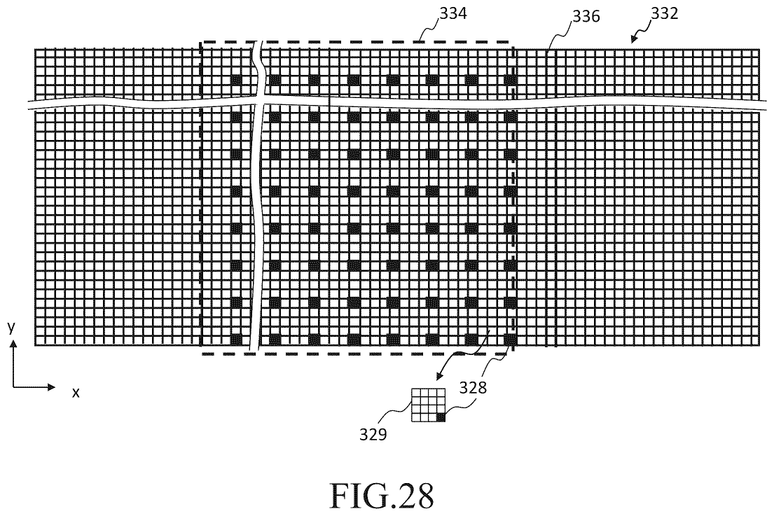

FIG. 28 is a diagram showing an example of an irradiation region and a writing target pixel of multiple beams according to the fourth embodiment. In FIG. 28, a stripe region 332 is divided into a plurality of mesh regions by the beam size of the multiple beams, for example. Each mesh region serves as a writing target pixel 336. The size of the writing target pixel 336 is not limited to the beam size, and may be any size regardless of the beam size. For example, it may be 1/n (n being an integer of 1 or more) of the beam size. FIG. 12 shows the case where the writing region of the target object 101 is divided, for example, in the y direction, into a plurality of stripe regions 332 by the width size being substantially the same as the size of an irradiation region 334 which can be irradiated by one irradiation with the multiple beams 21. The width of the stripe region 332 is not limited to this. Preferably, the width of the stripe region 332 is n times (n being an integer of 1 or more) the size of the irradiation region 334. In the irradiation region 334, there are shown a plurality of pixels 328 which can be irradiated with one shot of the multiple beams 21. In other words, the pitch between adjacent pixels 328 is the beam pitch of the multiple beams. In the example of FIG. 28, the pitch between the pixels 328 is also each pitch of the multiple beams on the surface of the target object 101, and is, for example, four times the size of a pixel. One sub-irradiation region 329 is composed of a group of pixels which fill a region of the pitches between the pixels 328. In the case of FIG. 28, each sub-irradiation region 329 is composed of 4×4 pixels.

For example, when the irradiation region 334 is fixed (tracking fixation) to one point on the target object 101 by the deflector 208, each shot is performed while a corresponding beam is shifted by the deflector 209, in the row or column in the sub-irradiation region 329. Then, after the pixels 336 in the row or column in the sub-irradiation region 329 have been irradiated, tracking is reset, and then, the irradiation region 334 is shifted by, for example, one pixel 336 and again fixed. At this process, controlling is performed so that a beam different from the last beam may be used as the beam in charge of the sub-irradiation region 329. By repeating this operation, all the pixels 336 in the stripe region 332 serve as irradiation targets. Then, by applying any one of the multiple beams to a necessary pixel 336, a desired figure pattern has been written as a whole.

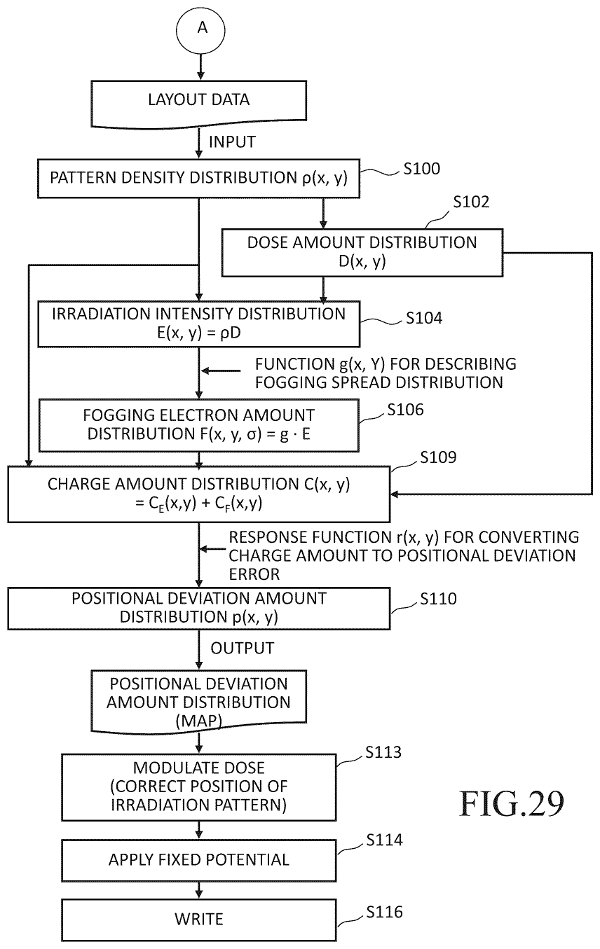

FIG. 29 is a flowchart showing the rest of an example of main steps of a writing method according to the fourth embodiment. FIG. 29 is the same as FIG. 24 except that a dose modulating step (S113) is executed instead of the deflection position correcting step (S112). Further in the fourth embodiment, some parts of the flowchart showing a main step example of the writing method in FIG. 23 are applied.

The contents of each step from the fixed potential applying step (S90) to the positional deviation amount distribution p(x,y) calculating step (S110) are the same as those of the third embodiment when reading by replacing the target object 2 with the target object 101, and the electrode substrate 20 with the electrode substrate 220.

In the third embodiment, in order to correct a positional deviation, the irradiation position of each shot figure defined in shot data is corrected, and a deflection amount is calculated to perform deflection to a corrected position. By contrast, in the fourth embodiment, a pattern is formed by applying or not applying irradiation of the multiple beams 21 to a necessary pixel 36, and by modulating its dose. Further, beam deflection is collectively executed, using the deflectors 208 and 209, for all the multiple beams. Therefore, it is difficult to correct a deflection position of an individual beam. Then, according to the fourth embodiment, the position of an irradiation pattern (pixel pattern) formed after irradiation is corrected by modulating doses to the pixel 336 whose position deviates due to charging, and to the surrounding pixels of the pixel 336.

Here, the shot data generation unit 41 calculates an irradiation time for each pixel 336. The irradiation time can be obtained by dividing a dose amount defined in the dose amount distribution D(x,y) by a current density J.

In the dose modulating step (S113), referring to a positional deviation amount shown in the positional deviation amount distribution (positional deviation map), the dose modulation unit 47 modulates doses to the pixel 336 which is irradiated with a corresponding beam in the multiple beams, and to the surrounding pixels of the pixel 336 so that, as a result of irradiation with the multiple beams 21, an irradiation pattern may be formed at the irradiation position to be corrected.

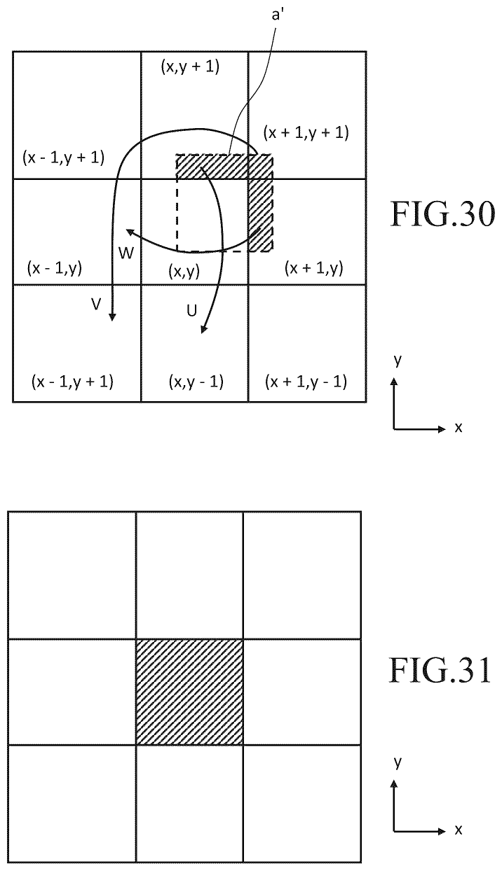

FIGS. 30 and 31 are illustrations showing an example of a method for correcting a positional deviation according to the fourth embodiment. FIG. 30 shows the case where a beam “a′” irradiating the pixel at coordinates (x,y) causes a positional deviation in the +x and +y directions. In order to correct the deviated position of the pattern formed by the beam “a′” with such a positional deviation to the position corresponding to the pixel at the coordinates (x,y) as shown in FIG. 31, correction can be accomplished by distributing the dose corresponding to the deviated position to a pixel located opposite to the direction of deviated surrounding pixels. In the example of FIG. 30, the dose deviated to the pixel at coordinates (x,y+1) should be distributed to the pixel at coordinates (x,y−1). The dose deviated to the pixel at coordinates (x+1,y) should be distributed to the pixel at coordinates (x−1,y). The dose deviated to the pixel at coordinates (x+1,y+1) should be distributed to the pixel at coordinates (x−1,y−1).

In proportion to a ratio of the area displaced due to a positional deviation of the beam to the pixel at (x,y), the dose modulation unit 47 calculates a modulation rate of a beam to the pixel at (x,y) and modulation rates of beams to the pixels at (x,y−1), (x−1,y), and (x−1,y−1) which surround the pixel (x,y). Specifically, the dose modulation unit 47 calculates, for each of surrounding pixels, a displacement ratio by dividing the displaced amount by a total beam area, extracts the irradiation amount equivalent to the distributed amount of the displacement ratio from the irradiation amount applied to the pixel concerned, and allots the extracted irradiation amount to a pixel located opposite to the overlapped pixel.

In the case of FIG. 30, the area ratio displaced to the pixel at coordinates (x,y+1) can be calculated by (“x direction beam size”−“x direction deviation amount”)×“y direction deviation amount”/(“x direction beam size”×“y direction beam size”). Therefore, a distribution amount U to be distributed for correction to the pixel at coordinates (x,y−1) can be calculated by (“x direction beam size”−“x direction deviation amount”)×“y direction deviation amount”/(“x direction beam size”×“y direction beam size”).

Also, in the case of FIG. 30, the area ratio displaced to the pixel at coordinates (x+1,y+1) can be calculated by “x direction deviation amount”×“y direction deviation amount”/(“x direction beam size”×“y direction beam size”). Therefore, a distribution amount V to be distributed for correction to the pixel at coordinates (x−1,y−1) can be calculated by “x direction deviation amount”×“y direction deviation amount”/(“x direction beam size”×“y direction beam size”).

Also, in the case of FIG. 30, the area ratio displaced to the pixel at coordinates (x+1,y) can be calculated by “x direction deviation amount” x (“y direction beam size”−“y direction deviation amount”)/(“x direction beam size”×“y direction beam size”). Therefore, a distribution amount W to be distributed for correction to the pixel at coordinates (x−1,y) can be calculated by “x direction deviation amount”×(“y direction beam size”−“y direction deviation amount”)/(“x direction beam size”×“y direction beam size”).

Consequently, a modulation rate D of the beam to the pixel at coordinates (x, y), which remains without being distributed, can be calculated by 1-U-V-W.

The dose modulation unit 47 performs dose modulation of the pixel 336 by multiplying the dose (irradiation time) of a corresponding pixel by an obtained modulation rate.

In the fixed potential applying step (S114), the potential applying circuit 48 applies a constant voltage to the target object 101 or the electrode substrate 220 so that the electrode substrate 220 may have a positive fixed potential with respect to the target object 101. Here, for example, in the state where the target object 101 is connected to the ground, a positive voltage is applied to the electrode substrate 220. Thereby, an unchanging constant electric field where the electrode substrate 220 has a positive electric potential with respect to the target object 101 can be produced.

In the writing step (S116), the electron optical column 102 (column) individually applies a beam with a modulated dose to the object pixel 336 and surrounding pixels 336 which surround the pixel 336 concerned. Thereby, the writing mechanism 350 writes a pattern at a charge-corrected position on the target object 101, in the state of an unchanging constant electric field where the electrode substrate 220 has a positive potential with respect to the target object 101.

In the example described above, a positive voltage is applied to the electrode substrate 220 from the potential applying circuit 48, and the target object 101 is connected to the ground through a pin of the substrate cover 222 (not shown) in order to be a GND potential.

It is also preferable as described above that the electrode substrate 220 is connected to the ground to be a GND potential, and a negative voltage is applied to the target object 101 from the potential applying circuit 48 through the pin of the substrate cover 222.

Then, similarly to the case described in reference to FIG. 9, the electrostatic lens 25 may be arranged at a position such that the electric field between the electrode substrate 220 and the target object 101 is not included in the influence range of the electric field of the electrostatic lens 25. In other words, the electrostatic lens 25 is disposed upstream to the extent that the electric field between the electrode substrate 220 and the target object 101 is not affected. In further other words, the electrode substrate 220 is disposed at the position where the electric field due to the electrostatic lens 25 has been sufficiently attenuated. It is also preferable to perform dynamic focusing with the electrostatic lens 25, along the asperity of the surface of the target object 101.

It goes without saying that the above-described pole piece 20a of the objective lens, conductive backscattered electron prevention plate 20b, conductive thermal shielding mechanism 20c, conductive objective lens holding member 20d, or conductive cylindrical electrode 20e can be used instead of the electrode substrate 220.

Further, similarly to the case of FIG. 17, according to the second embodiment, such positional deviation is corrected by correcting the deflection sensitivity of the electron beam 6.

As described above, according to the fourth embodiment, it is possible in multiple electron beam writing to correct a positional deviation of an electron beam attributed to a charge amount while preventing emitted secondary electrons, etc. from returning to the target object 101.

### Fifth Embodiment

In a fifth embodiment, there is described a configuration for correcting an array shape of multiple electron beams while preventing emitted secondary electrons, etc. from returning to the target object. The contents of the fifth embodiment are the same as those of the fourth embodiment except what is specifically described below.

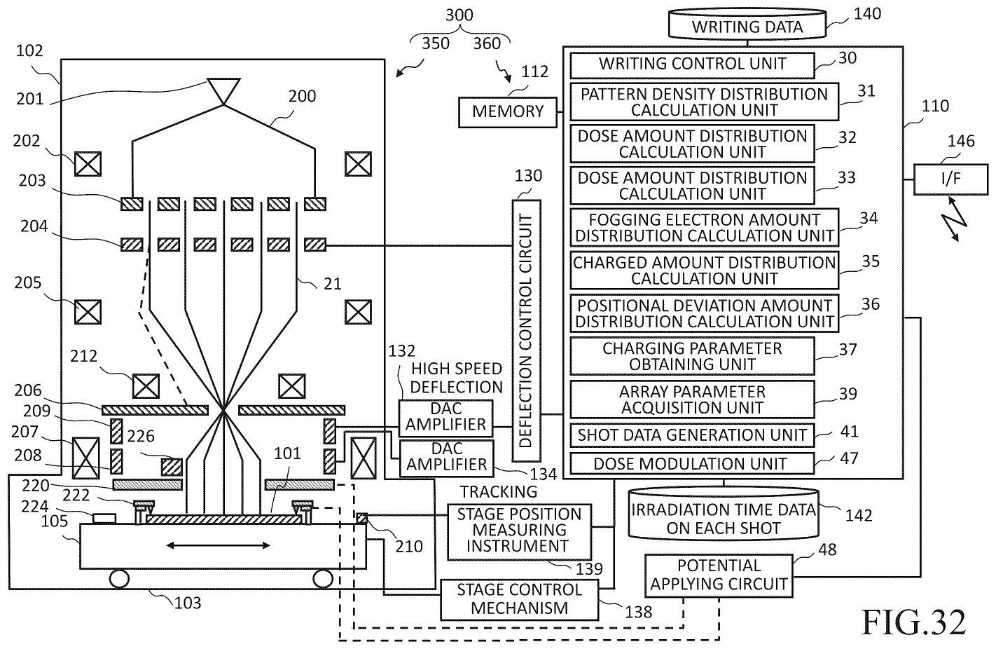

FIG. 32 is a block diagram showing an example of the configuration of a writing apparatus according to the fifth embodiment. The contents of FIG. 32 are the same as those of FIG. 27 except that a quadrupole lens 212 is arranged between the reducing lens 205 and the objective lens 207, and, further in the control computer 110, there is arranged an array parameter acquisition unit 39.

Each of the “units” such as the writing control unit 30, the pattern area density distribution calculation unit 31, the dose amount distribution calculation unit 32, the irradiation intensity calculation unit 33, the fogging electron amount distribution calculation unit 34, the charge amount distribution calculation unit 35, the positional deviation amount distribution calculation unit 36, the charging parameter acquisition unit 37, the array parameter acquisition unit 39, the shot data generation unit 41, and the dose modulation unit 47 includes processing circuitry. The processing circuitry includes an electric circuit, a computer, a processor, a circuit board, a quantum circuit, a semiconductor device, or the like. Each of the “units” may use common processing circuitry (the same processing circuitry), or different processing circuitry (separate processing circuitry). Input data required in the writing control unit 30, the pattern area density distribution calculation unit 31, the dose amount distribution calculation unit 32, the irradiation intensity calculation unit 33, the fogging electron amount distribution calculation unit 34, the charge amount distribution calculation unit 35, the positional deviation amount distribution calculation unit 36, the charging parameter acquisition unit 37, the array parameter acquisition unit 39, the shot data generation unit 41, and the dose modulation unit 47, or calculated results are stored in the memory 141 each time.

It is also preferable that the quadrupole lens 212 is an electrostatic type quadrupole lens composed of four electrodes, or a magnetic field type quadrupole lens composed of four magnetic poles each having a coil.

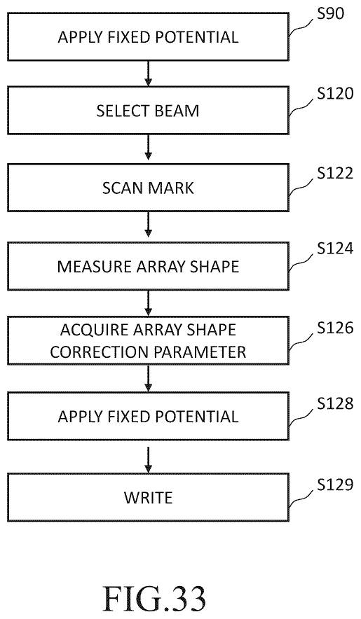

FIG. 33 is a flowchart showing an example of main steps of a writing method according to the fifth embodiment. In FIG. 33, the writing method of the fifth embodiment executes a series of steps: the fixed potential applying step (S90), a beam selecting step (S120), a mark scanning step (S122), an array shape measuring step (S124), an array shape correction parameter acquiring step (S126), a fixed potential applying step (S128), and a writing step (S129).

As described above, when a structure exits in the state where an electric field has been produced between the electrode substrate 220 and the target object 101, especially when the structure is overlapped with a part of the target object 101, the potential of the surface of the target object 101 is not a constant value, and therefore, a potential distribution is generated on the target object 101 surface. Thereby, a positional deviation may occur at the irradiation positions of the multiple beams 21. Such positional deviation can be regarded as generated due to distortion of the array shape of the multiple beams 21. Then, according to the fifth embodiment, such positional deviation is corrected by correcting the distortion of the array shape of the multiple beams 21.

In the fixed potential applying step (S90), the potential applying circuit 48 applies a potential which has been set as a certain value for making the electrode substrate 220 have a positive potential with respect to the target object 101 to the electrode substrate 220 or the target object 101. Here, for example, in the state where the target object 101 is connected to the ground, a positive potential is applied to the electrode substrate 220. Thereby, an electric field where the electrode substrate 220 has a positive electric potential with respect to the target object 101 can be produced.

In the beam selecting step (S120), a plurality of groups each composed of a plurality of adjacent beams in the multiple beams 21 are set. Then, a plurality of beams to be used are selected. For example, when the multiple beams 21 of 512×512 beams are formed, each group is set to have, for example, 32×32 beams. The number of beams may be set appropriately. For example, a beam array region is divided into regions of 5×5 grids. Then, each group is formed based on a beam of the position of each grid, for irradiating each grid.

Beam selection is performed using the blanking aperture array mechanism 204. Beams to be selected are set as beam ON, and the other beams are set as beam OFF.

In the mark scanning step (S122), first, the XY stage 105 is moved so that the center of the mark 224 may be located at the deflection center of the deflector 209. For example, the XY stage 105 is moved so that the center of the mark 224 may be located at the central axis of the trajectory of the multiple beams 21.

In the state of an unchanging fixed electric field where the electrode substrate 220 has a positive electric potential with respect to the target object 101 having been produced, the writing mechanism 350 scans a cross pattern on the mark with selected beams, using the deflector 209. At this process, the detector 226 detects a secondary electron emitted from the mark 224. Information detected at each position is output to the control computer 110 through a detection circuit (not shown).

While changing a selected group of beams, the beam selecting step (S120) and the mark scanning step (S122) are repeated.

In the array shape measuring step (S124), the writing control unit 30 calculates each position of a plurality of detected cross patterns, and measures the array shape of the multiple beams 21 in the state where a fixed potential has been applied to the target object 101 or the electrode substrate 220.

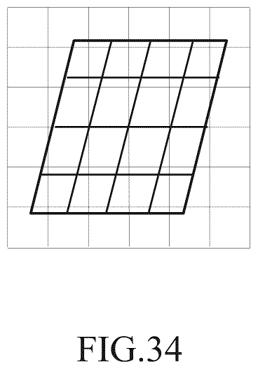

FIG. 34 is an illustration showing an example of an array shape according to the fifth embodiment. FIG. 34 shows each measured position (thick line) superimposed on each design position. As shown in FIG. 34, based on the potential distribution on the surface of the target object 101, it turns out that distortion occurs in the array shape of the multiple beams 21.

In the array shape correction parameter acquiring step (S126), the array parameter acquisition unit 39 (another example of the correction circuit) corrects a positional deviation of the multiple beams 21 by correcting a deviation of the beam array shape of the multiple beams 21. Therefore, the array parameter acquisition unit 39 calculates a parameter for correcting the array shape of the multiple beams 21 to the design array shape (quadrangle). Specifically, a parameter is obtained which adjusts the rotation amount of the multiple-beam image and the expansion/contraction amount in the x and y directions of the multiple-beam image. Correction of the array shape of the multiple beams 21 is executed by adjusting the lens effect of the quadrupole lens 212 and that of the objective lens 207. Accordingly, a parameter for correcting an excitation value of the quadrupole lens 212 and that of the objective lens 207 is calculated.

The x and y direction sizes of the beam array shape are adjusted by applying voltages to the four electrodes of the quadrupole lens 212 so that, for example, one pair of two facing electrodes aligned in the x direction may be a positive electrode (or negative electrode), and so that the other pair of two facing electrodes aligned in the y direction may be a negative electrode (or positive electrode). The shape is adjusted by that the beam array extends in the x direction by being pulled by the positive electrode, and it shortens in the y direction by being compressed by the negative electrode. Further, the rotation amount of the image is adjusted with the objective lens 207 or other electromagnetic lens. The acquired parameter is output to a lens control circuit (not shown) and set therein.

The steps up to this step are carried out as preprocessing of the writing processing. Next, the target object 101 on which a pattern is actually to be written is placed on the XY stage 105, and then, the writing processing is started.

In the fixed potential applying step (S128), the potential applying circuit 48 applies a potential which has been set as a certain value for making the electrode substrate 220 have a positive potential with respect to the target object 101 to the electrode substrate 220 or the target object 101. Here, for example, in the state where the target object 101 is connected to the ground, a positive potential is applied to the electrode substrate 220. Thereby, an electric field where the electrode substrate 220 has a positive electric potential with respect to the target object 101 can be produced.

Here, the shot data generation unit 41 calculates an irradiation time for each pixel 336.

In the writing step (S129), the writing mechanism 350 writes, using the multiple beams 21 whose beam array shape has been corrected, a pattern on the target object 101 in the state of an electric field having been produced where the electrode substrate 220 has a positive electric potential with respect to the target object 101.

As described above, according to the fifth embodiment, it is possible in multiple electron beam writing to correct a positional deviation of the multiple beams 21 by correcting the beam array shape while preventing emitted secondary electrons, etc. from returning to the target object.

Embodiments have been explained referring to specific examples described above. However, the present invention is not limited to these specific examples.

While the apparatus configuration, control method, and others not directly necessary for explaining the present invention are not described, it is needless to say that they can be appropriately selected and used when needed. For example, although description of the configuration of the control unit for controlling the writing apparatus 100 or 300 is omitted, it can obviously be selected and used appropriately when necessary.

Any electron beam writing apparatus and electron beam writing method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electron beam writing apparatus comprising:
an emission source configured to emit an electron beam;
a stage configured to mount thereon a target object on which a pattern is to be written with the electron beam;
a potential regulating member arranged to be upstream of the target object in a case where the target object is placed on the stage and in a state where no electrode to which a variable potential is applied during writing is arranged between the target object and the potential regulating member, and configured to be set to have a fixed potential being positive with respect to the target object;
a potential applying circuit configured to apply a voltage to one of the target object and the potential regulating member so that the potential regulating member has the fixed potential; and
a correction circuit configured to correct a positional deviation of the electron beam on a surface of the target object which occurs in a case where the target object is irradiated with the electron beam in a state in which the potential regulating member has the fixed potential.

2. The apparatus according to claim 1, wherein, only at an upstream of the potential regulating member, an electrode is disposed to which an electric potential being variable during writing is applied.

3. The apparatus according to claim 1, wherein the correction circuit corrects the positional deviation attributed to a potential distribution formed on the surface of the target object in the state in which the potential regulating member has the fixed potential.

4. The apparatus according to claim 3, further comprising:
a structure configured to generate the potential distribution.

5. The apparatus according to claim 1, wherein
the surface of the target object is coated with resist, and
the correction circuit corrects the positional deviation due to charging of the resist.

6. The apparatus according to claim 1, wherein
the target object is irradiated with multiple electron beams, and
the correction circuit corrects the positional deviation by correcting a deviation of a beam array shape of the multiple electron beams.

7. The apparatus according to claim 1, further comprising:
a deflector configured to deflect the electron beam onto the target object, wherein
the correction circuit corrects the positional deviation by correcting deflection sensitivity of the electron beam.

8. The according to claim 1, further comprising:
another potential regulating member arranged between the target object and the potential regulating member, and configured to be controlled to be equipotential with the target object.

9. The apparatus according to claim 1, further comprising:
an objective lens configured to generate a magnetic field, and to focus the electron beam on the surface of the target object, wherein
the potential regulating member has a surface extending, at an inner peripheral side of the objective lens, from a height position closer to the target object than to the objective lens to a height position where an intensity of the magnetic field of the objective lens is one of less than and equal to a threshold.

10. The apparatus according to claim 1, wherein, as the potential regulating member, an electrode substrate where an opening through which the electron beam passes is formed at its central part is used.

11. The apparatus according to claim 1,
further comprising an objective lens that forms an image of the electron beam on the sample surface,
wherein a pole piece of the objective lens is used as the potential regulating member.

12. An electron beam writing method comprising:
applying a constant voltage to one of a target object, which is placed on a stage, and a potential regulating member, which is arranged at an upstream of the target object, in a state where no electrode to which a variable potential is applied during writing is arranged between the target object and the potential regulating member, so that the potential regulating member has a fixed potential being positive with respect to the target object;
correcting a positional deviation of an electron beam on a surface of the target object which occurs in a case where the target object is irradiated with the electron beam in a state in which the potential regulating member has the fixed potential; and
writing a pattern on the target object with the electron beam.
